(19) United States
(12) Patent Application Publication
(10) Pub. No.: US 2016/0334705 A1
(43) Pub. Date: Nov. 17, 2016

(54) LITHOGRAPHIC PRINTING PLATE PRECURSOR

(71) Applicants: Masamichi KAMIYA, Gunma (JP); Yoshiaki SEKIGUCHI, Gunma (JP); Koji HAYASHI, Gunma (JP); Eiji HAYAKAWA, Gunma (JP); EAST MAN KODAK COMPANY, Rochester, NY (US)

(72) Inventors: Masamichi Kamiya, Oura-gun (JP); Yoshiaki Sekiguchi, Kumagaya-shi (JP); Koji Hayashi, Tatebayashi-shi (JP); Eiji Hayakawa, Utsunomiya-shi (JP)

(21) Appl. No.: 15/111,283

(22) PCT Filed: Mar. 3, 2015
(86) PCT No.: PCT/JP2015/056762

§ 371 Date: Jul. 13, 2016

(30) Foreign Application Priority Data
Apr. 11, 2014 (JP) 2014-081755

(51) Int. Cl. G03F 7/033; G03F 7/32; B41C 1/10; G03F 7/20

(52) U.S. Cl. CPC G03F 7/033; G03F 7/20; G03F 7/32; B41C 1/1008; B41C 2210/24

(57) ABSTRACT

The present invention relates to a lithographic printing plate precursor, comprising: a substrate; and an imaging layer formed on the substrate, wherein the imaging layer is prepared from a composition comprising at least one radical-polymerizable compound, at least one radical polymerization initiator, and at least one polymer particle which has an average particle diameter of 300 nm or more, and two or more poly(alkyleneoxide) moieties. The present invention can provide a lithographic printing plate precursor which is on-press developable and has excellent on-press development stability overtime and printing properties.

### FIELD OF THE INVENTION

The present invention relates to a lithographic printing plate precursor. More particularly, the present invention relates to an infrared-sensitive or heat-sensitive lithographic printing plate precursor which is used as a so-called computer-to-plate (CTP) plate capable of directly recording images by irradiation with infrared rays from a solid laser or a semiconductor laser corresponding to digital signals.

### BACKGROUND OF THE INVENTION

With the progress of computer image processing techniques, a method of directly recording images on a photosensitive layer by irradiation corresponding to digital signals has recently been developed, and thus there has been intense interest in a computer-to-plate (CTP) system in which images are directly formed on a lithographic printing plate precursor, without outputting onto a silver salt mask film, by employing the method using a lithographic printing plate precursor. The CTP system, which uses a high-output laser having a maximum intensity within a near infrared or infrared range as a light source for the irradiation, has the following advantages: images having high resolution can be obtained by exposure within a short time and the lithographic printing plate precursor used in the system can be handled in daylight. Regarding solid and semiconductor lasers capable of emitting infrared rays having a wavelength of 760 to 1,200 nm, high-output and portable lasers are readily available.

Also, as a lithographic printing plate precursor which can form images using a solid laser or semiconductor laser, JP2005-522362A, JP2008-503365A, JP2010-234586A, JP2011-068006A, and JP2011-177983A disclose so-called on-press developable precursors which do not need any conventional developing process after a light exposure process, but unnecessary parts of an image-recording layer can be removed with a fountain solution or ink on press.

### SUMMARY OF THE INVENTION

The on-press developable lithographic printing plate precursors as proposed in JP2005-522362A, JP2008-503365A, JP2010-234586A, JP2011-068006A, and JP2011-177983A do not require any waste treatment process which is necessary in a conventional developing process, and therefore have fewer effects on the environment.

However, further improvements in the on-press development stability over time and printing properties of the above on-press developable lithographic printing plate precursors are needed.

The present invention was completed in view of the above circumstances, and an objective thereof is to provide a lithographic printing plate precursor which is on-press developable and has excellent on-press development stability over time and printing properties.

The above objective of the present invention can be achieved by a lithographic printing plate precursor, comprising:

a substrate; and

an imaging layer, formed on the substrate,

wherein:

the imaging layer is prepared from a composition comprising:

at least one radical-polymerizable compound,

at least one radical polymerization initiator, and

at least one polymer particle that has an average particle diameter of 300 nm or more, and two or more poly(alkyleneoxide) moieties.

It is desirable that the average particle diameter of the polymer particle ranges from 300 to 2000 nm.

It is also desirable that the polymer which has two or more types of poly(alkyleneoxide) moieties be a polymer having: a main chain which comprises no poly(alkyleneoxide) moiety, and two or more pendant groups comprising the two or more types of poly(alkyleneoxide) moieties. Each poly(alkyleneoxide) can be a poly(alkyleneoxide) composed of a single type of alkyleneoxide, or can be a poly(alkyleneoxide) having a block structure or structures composed of two or more different alkyleneoxides.

The pendant group can be represented by any of the general formulae (1) through (4), wherein general formula (1) is:

—COO—[(CH₂)ₓ(CH(R¹))O]_{y}—R² (1)

general formula (2) is:

—COO—[(CH(R¹))(CH₂)ₓO]_{y}—R² (2)

wherein in general formulae (1) and (2),

x is an integer from 1 to 5,

y is an integer from 1 to 400,

R¹ independently denotes a hydrogen atom or a methyl group, and

R² denotes a hydrogen atom or a monovalent hydrocarbon group having 1 to 8 carbon atoms,

general formula (3) is:

—COO—[(CH₂)_{z}(CH(R³))O]ₘ—[(CH₂)ₙ(CH(R⁴))O]_{q}—R⁵ (3)

and general formula (4) is:

—COO—[(CH(R³))(CH₂)_{z}O]ₘ—[(CH(R⁴))(CH₂)ₙO]_{q}—R⁵ (4)

wherein in general formulae (3) and (4),

each of n and z is independently an integer from 1 to 5,

each of m and q is independently an integer from 1 to 200,

R³ and R⁴ independently denotes a hydrogen atom or a methyl group, provided that R³ and R⁴ are different if n and z are the same number, and

R⁵ denotes a hydrogen atom or a monovalent hydrocarbon group having 1 to 8 carbon atoms.

It is desirable that the polymer be at least derived from at least two selected from the group consisting of poly(alkyleneglycol)alkylether(meth)acrylates and poly(alkyleneglycol)(meth)acrylates.

The polymer can further have at least one group selected from the group consisting of a cyano group, an aryl group and an amide group. In this case, it is preferable that the polymer be at least derived from at least two selected from the group consisting of poly(alkyleneglycol)alkylether(meth)acrylates and poly(alkyleneglycol)(meth)acrylates, and (meth)acrylonitrile, styrene, (meth)acrylamide, or a combination thereof.

The polymer particle can be present in the imaging layer in an amount of from 1 to 60% by mass, based on the solid content of the imaging layer.

The radical-polymerizable compound can have at least one poly(alkyleneoxide) moiety.

For example, the radical-polymerizable compound can be a multi-functional urethane acrylate. In this case, it is preferable that the multi-functional urethane acrylate has a molecular weight of 2000 or more.

It is preferable that the radical polymerization initiator comprises a heat-polymerization initiator such as an onium salt.

It is preferable that the radical polymerization initiator comprises a photo-thermal conversion material such as a cyanine dye.

The present invention also relates to a process for preparing a lithographic printing plate, comprising a step of on-press developing the above lithographic printing plate precursor. The process can comprise the steps of: image-wise exposing the lithographic printing plate precursor; mounting the lithographic printing plate precursor on press; and on-press developing the lithographic printing plate precursor by contacting it with either ink, a fountain solution, or both an ink and fountain solution, in this order. Alternatively, the process can comprise the steps of: mounting the lithographic printing plate precursor on press; image-wise exposing the lithographic printing plate precursor; and on-press developing the lithographic printing plate precursor by contacting it with either ink, a fountain solution, or both an ink and fountain solution, in this order.

The lithographic printing plate precursor according to the present invention is on-press developable, and has excellent on-press development stability over time and printing properties. In particular, the lithographic printing plate precursor according to the present invention has good ink receptivity, can be rapidly developed on press, can be preserved for a long period of time, and can exhibit a long printing press life.

It is also possible to form images on the lithographic printing plate precursor according to the present invention by laser exposure.

The lithographic printing plate precursor according to the present invention does not need any normal developing process, and therefore does not need any waste treatment process for a developer which is required in the normal developing process. Accordingly, it is possible to prepare a lithographic printing plate in a relatively short period of time with a lithographic printing plate precursor according to the present invention, and to control the effects on the environment caused by the preparation (making up) of the lithographic printing plate.

### DETAILED DESCRIPTION OF THE INVENTION

The lithographic printing plate precursor according to the present invention comprises a substrate, and an imaging layer, formed on the substrate, wherein the imaging layer is prepared from a composition comprising:

at least one radical-polymerizable compound,

at least one radical polymerization initiator, and

at least one polymer particle that has an average particle diameter of 300 nm or more, and comprises two or more types of poly(alkyleneoxide) moieties.

A lithographic printing plate precursor can be referred to as a photosensitive lithographic printing plate.

### Substrate

As the substrate in the lithographic printing plate precursor according to the present invention, any substrate can be used as long as it has properties, such as strength, durability and flexibility, which are necessary for use in lithographic printing plates.

As the substrate, mention can be made of metal plates made of aluminum, zinc, copper, stainless steel, and iron; plastic films made of polyethylene terephthalate, polycarbonate, polyvinyl acetal, polyethylene, etc.; composite materials obtained by forming a metal layer on papers which are melt-coated with a synthetic resin or coated with a synthetic resin solution, plastic films and the like, using technologies such as vacuum deposition and laminating; and a material used as the substrate of the lithographic printing plate. It is particularly preferred to use a substrate made of aluminum or a composite substrate in which a substrate made from material(s) other than aluminum is coated with aluminum.

It is preferred that the surface of the aluminum substrate is surface-treated for the purpose of enhancing water retentivity and improving adhesion with an imaging layer or an optionally formed intermediate layer. Examples of the surface treatment include roughening treatments such as a brush graining method, a ball graining method, electrolytic etching, chemical etching, liquid honing, and sandblasting, and a combination thereof. Among these, a roughening treatment including use of electrolytic etching is particularly preferred.

As an electrolytic bath in the case of electrolytic etching, for example, an aqueous solution or an aqueous solution containing an organic solvent, containing an acid, an alkali or a salt thereof is used. Among these, an electrolytic solution containing hydrochloric acid, nitric acid, or a salt thereof is particularly preferred.

Furthermore, the aluminum substrate subjected to the roughening treatment is subjected to a desmutting treatment using an aqueous solution of an acid or an alkali, if necessary. It is preferred that the aluminum substrate thus obtained is subjected to an anodic oxidation treatment. It is particularly preferred that the anodic oxidation treatment is performed using a bath containing sulfuric acid or phosphoric acid. Furthermore, it is also preferable to perform, after the anodic oxidation treatment, a pore-widening treatment in which the size of the micropores in the coating prepared by the anodic oxidation treatment is enlarged, by contacting the coating with an acid or alkaline aqueous solution. In each case, it is preferable that the coating be treated such that the pore size or pore diameter of the micropores on the coating is in a range of from 5 to 100 nm. The pore size for sulfuric acid anodization is typically less than 20 nm, whereas the pore size for phosphoric acid anodization is typically 20 nm or more. It can be preferable for the anodized substrate to have pores with a size of 20 nm or more, for example 20 to 100 nm, on the surface thereof.

It is preferable to use an aluminum substrate which is subjected to a hydrophilization treatment, after the roughening treatment (graining treatment) and the anodic oxidation treatment. As the hydrophilization treatment, mention can be made of, a sealing treatment by immersing an aluminum substrate in a hot aqueous solution containing hot water and an inorganic salt or an organic salt, or performed using a steam bath; a silicate treatment (for example, sodium silicate, potassium silicate); a potassium fluorozirconate treatment; a phosphomolybdate treatment; an alkyl titanate treatment; a polyacrylic acid treatment; a polyvinylsulfonic acid treatment; a polyvinylphosphonic acid treatment; a phytic acid treatment; a treatment with a hydrophilic organic polymer compound and a divalent metal salt; a hydrophilization treatment by undercoating with a water soluble polymer having a sulfonic acid group, a carboxylic acid group, an amide group or two or more thereof; a coloring treatment with an acidic dye; electrodeposition with silicate; and a treatment with a mixed solution of a fluorine-compound and a phosphate compound as described in, for example, paragraph [0048], in particular paragraph [0055], of JP-A-2011-215476. It is preferable for the surface of the substrate to have an underlayer comprising at least one water-soluble polymer such as polyacrylic acid.

### Imaging Layer

The lithographic printing plate precursor according to the present invention comprises at least one imaging layer. If necessary, it may can comprise a plurality of imaging layers. An imaging layer can be referred to as a photosensitive layer. The lithographic printing plate precursor according to the present invention comprises at least a negative-working imaging layer in which imagewise exposed portions thereof are cured or hardened to form imaging portions. The imaging layer is preferably of the thermal negative working type, in which irradiated portions with an IR-laser are cored or hardened to form imaging portions.

The imaging layer in the lithographic printing plate precursor according to the present invention is prepared from a composition comprising (A) at least one radical-polymerizable compound, (B) at least one radical polymerization initiator, and (C) at least one polymer particle that has an average particle diameter of 300 nm or more, and comprises two or more types of poly(alkyleneoxide) moieties. Thus, the imaging layer comprises at least the above components (A) to (C). Hereafter, the above components (A) to (C) will be described.

### Radical-Polymerizable Compound

The radical-polymerizable compound according to the present invention is a compound that is capable of radical polymerization. The radical-polymerizable compound can be a single compound or a combination of a plurality of compounds.

The radical-polymerizable compound is not specifically limited, but is preferably a compound having an addition-polymerizable ethylenically unsaturated bond. The compound can be optionally selected from compounds having at least one, and preferably two or more ethylenically unsaturated double bond groups at the end. The compound has chemical forms, for example, monomer and prepolymer such as dimer, trimer and oligomer, or mixtures thereof and copolymers thereof. Examples of the monomer and the copolymer thereof include an ester of an unsaturated carboxylic acid (for example, acrylic acid, methacrylic acid, itaconic acid, crotonic acid, isocrotonic acid, maleic acid, etc.) and an aliphatic polyhydric alcohol compound, and an amide of an unsaturated carboxylic acid and an aliphatic polyhydric amine compound.

Specific examples of the ester of the aliphatic polyhydric alcohol compound and the carboxylic acid include acrylate esters such as ethylene glycol diacrylate, triethylene glycol diacrylate, 1,3-butanediol diacrylate, tetramethylene glycol diacrylate, propyleneglycol diacrylate, neopentyl glycol diacrylate, trimethylolpropane triacrylate, trimethylolpropanetri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol pentaacrylate, dipentaerythrito hexaacrylate, sorbitol triacrylate, sorbitol tetraacrylate, sorbitol pentaacrylate, sorbitol hexaacrylate, tri(acroyloxyethyl) isocyanurate, and polyester acrylate oligomer.

Examples of methacrylate esters include tetramethylene glycol dimethacrylate, triethylene glycol dimethacrylate, neopentylglycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, dipentaerythritol pentamethacrylate, sorbitol trimethacrylate, sorbitol tetramethacrylate, bis[p-(3-methacryloxy-2-hydroxypropoxy)phenyl]dimethylmethane and bis-[p-(methacryloxyethoxy)phenyl]dimethylmethane.

Examples of itaconate esters include ethylene glycol diitaconate, propylene glycol diitaconate, 1,3-butanediol diitaconate, 1,4-butanediol diitaconate, tetramethylene glycol diitaconate, pentaerythritol diitaconate, and sorbitolte traitaconate.

Examples of crotonate esters include ethylene glycol dicrotonate, tetramethylene glycol dicrotonate, pentaerythritol dicrotonate, and sorbitol tetradicrotonate.

Examples of isocrotonate ester include ethylene glycol diisocrotonate, pentaerythritol diisocrotonate, and sorbitol tetraisocrotonate.

Examples of maleate esters include ethylene glycol dimaleate, triethylene glycol dimaleate, pentaerythritol dimaleate, and sorbitol tetramaleate. Furthermore, mixtures of the above ester monomers can be utilized.

Specific examples of the amide of the aliphatic polyvalent amine compound and the unsaturated carboxylic acid include methylenebis-acrylamide, methylenebis-methacrylamide, 1,6-hexamethylenebis-acrylamide, 1,6-hexamethylenebis-methacrylamide, diethylenetriaminetrisacrylamide, xylylenebisacrylamide and xylylenebismethacrylamide.

As a preferable specific radical-polymerizable compound, mention can be made of SR399 marketed by Sartomer Company, having the following structure:

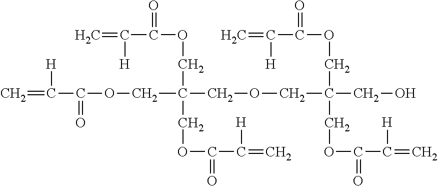 [SMILES: C=CC(=O)OCC(CO)(COCC(COC(=O)C=C)(COC(=O)C=C)COC(=O)C=C)COC(=O)C=C]

The radical-polymerizable compound can have at least one poly(alkyleneoxide) moiety.

As the alkyleneoxide, alkylene oxide with 2-6 carbon atoms is preferable, and ethylene oxide, propylene oxide, tetramethylene oxide, or hexamethylene oxide are particularly preferable. As the repeating number of alkylene oxides in the poly(alkyleneoxide) moiety, 1 to 50 is preferable, and 1 to 20 is more preferable.

The poly(alkyleneoxide) moiety can have a structure represented by the following general formula (1):

—COO—[(CH₂)ₓ(CH(R¹))O]_{y}—R² (1)

or the general formula (2):

—COO—[(CH(R¹))(CH₂)ₓO]_{y}—R² (2)

wherein,

x is an integer from 1 to 5,

y is an integer from 1 to 400,

R¹ independently denotes a hydrogen atom or a methyl group, and

R² denotes a hydrogen atom, a monovalent hydrocarbon group having 1 to 8 carbon atoms, or an organic group,

or the following general formula (3):

—COO—[(CH₂)_{z}(CH(R³))O]ₘ—[(CH₂)ₙ(CH(R⁴))O]_{q}—R⁵ (3)

or the following general formula (4):

—COO—[(CH(R³))(CH₂)_{z}O]ₘ—[(CH(R⁴))(CH₂)ₙO]_{q}—R⁵ (4)

wherein,

each of n and z is independently an integer from 1 to 5,

each of m and q is independently an integer from 1 to 200,

R³ and R⁴ independently denotes a hydrogen atom or a methyl group, provided that R³ and R⁴ are different if n and z are the same number, and

R⁵ denotes a hydrogen atom, a monovalent hydrocarbon group having 1 to 8 carbon atoms, or an organic group.

In the general formulae (1) and (2), y, m, and q can be an integer from 1 to 50, or from 1 to 20; R¹, R³, and R⁴ can be a hydrogen atom or a methyl group, or a hydrogen atom; the organic group for R² and R⁵ be an unsaturated carboxylic acid residue, more preferably an acryloyloxy group or a methacryloyloxy group or an acryloyloxy group.

As the radical-polymerizable compound with a poly(alkyleneoxide) moiety or moieties, an ester of an unsaturated carboxylic acid (for example, acrylic acid, methacrylic acid, itaconic acid, crotonic acid, isocrotonic acid, maleic acid, etc.) and an aliphatic polyhydric alcohol compound with a poly(alkyleneoxide) moiety or moieties at the ester portion(s) are useful.

As a suitable radical-polymerizable compound with poly(alkyleneoxide) moieties, mention can be made of SR602 marketed by Sartomer Company having the following structure:

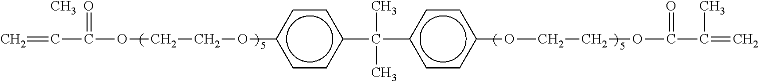

Other examples include a vinylurethane compound having two or more polymerizable vinyl groups in a molecule, which is obtained by adding the ester of the unsaturated carboxylic acid and the aliphatic polyhydric alcohol compound, or a vinyl monomer having a hydroxyl group represented by the following general formula (A) or (B) to a polyisocyanate compound having two or more isocyanate groups in a molecule such as hexamethylene diisocyanate. The compound to be reacted with an isocyanate group preferably has an amino group and an imino group in the molecule.

CH₂═C(Q¹)COOCH₂CH(Q²)OH (A)

wherein Q¹ and Q² independently represent H or CH₃.

(CH₂═C(Q¹)COOCH₂)ₐC(Q²)_{b}(Q³)_{c} (B)

wherein Q¹ and Q² independently represent H or CH₃, Q³ represents —CH₂OH, and a and c each independently represents an integer of 1 to 3 and b represents an integer of 0 or 1 or 2, provided that a+b+c is 4.

Mention can also be made of polyfunctional acrylates and methacrylates, for example, the urethane acrylates described in JP-A-S51-37193, the polyester acrylates described in JP-A-S48-64183, JP-A-S49-43191 and JP-A-S52-30490, and epoxy acrylates obtained by reacting an epoxy resin with (meth)acrylic acid. Furthermore, the photocurable monomers and oligomers described in the Journal of Japanese Adhesion Society, Vol. 20, No. 7, pp. 300-308 (1984) can be used.

Specific examples thereof include NK OLIGO U-4HA, U-4H, U-6HA, U-15HA, U-108A, U-1084A, U-200AX, U-122A, U-340A, U-324A, US-53H and UA-100 (which are manufactured by Shin-Nakamura Chemical Co., Ltd.); UA-306H, AI-600, UA-101T, UA-101I, UA-306T and UA-306I (which are manufactured by Kyoeisha Oil and Fats Chemical hid. Co., Ltd.); ART RESIN UN-9200A, UN-3320HA, UN-3320HB, UN-3320HC, SH-3800, SH-500, SH-9832 (which are manufactured by Negami Chemical Industrial Co., Ltd.); and Sartomer CN968, CN975, CN989, CN9001, CN9010, CN9025, CN9029, CN9165 and CN2260 (which are manufactured by Sartomer Company).

The radical-polymerizable compound U be a multi-functional urethane acrylate, preferably a multi-functional urethane acrylate with a functionality of 10 or more, or a multi-functional urethane acrylate with a functionality of 15 or more.

For example, the multi-functional urethane acrylate can have a molecular weight of 1000 or more, more preferably 1500 or more, and even more preferably 2000 or more. The molecular weight is based on a number-average molecular weight.

As a suitable multi-functional urethane acrylate, mention can be made of a polymerizable compound obtained by reacting Desmodur N100 (aliphatic polyisocyanate resin including hexamethylene diacrylates marketed by Bayer) with hydroxyethylacrylate(s) and pentaerythritoltriacrylate(s).

The radical-polymerizable compound can be present in the imaging layer or the composition for preparing the imaging later in an amount within the range from 10 to 90% by mass (weight), preferably from 20 to 80% by mass, and more preferably from 30 to 70% by mass, based on the solid content of the imaging layer or the composition for preparing the imaging later.

### Radical Polymerization Initiator

The radical polymerization initiator forms a radical or radicals to initiate the polymerization of the radical-polymerizable compound(s). The radical polymerization initiator may can be a single compound or a combination or system of a plurality of compounds.

### Heat-Polymerization Initiator and Photo-Polymerization Initiator

It is preferable that the radical polymerization initiator comprises at least one heat-polymerization initiator or at least one photo-polymerization initiator, or both.

As a heat-polymerization initiator or a photo-polymerization initiator, it is possible to use various heat-polymerization initiators and photo-polymerization initiators known from patent documents and non-patent documents alone or in combination (heat-polymerization initiation system or photo-polymerization initiation system) after appropriate selection according to temperature or the wavelength of a light source to be used. In the present invention, the heat-polymerization initiator(s) or the photo-polymerization initiator(s) to be used alone or in combination are merely referred to as a “heat-polymerization initiator” or “photo-polymerization initiator.”

As the heat-polymerization initiator, organic boron compounds, onium salts, and mixtures thereof are preferable. These heat-polymerization initiators can be used alone or in combination.

The organic boron compound can exhibit a function as a polymerization initiator by using it in combination with the photo-thermal converting material explained below. The organic boron compound is preferably an ammonium salt of a quaternary boron anion, which is represented by the following formula (2):

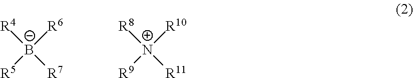

wherein:
R⁴, R⁵, R⁶ and R⁷ each independently represents an alkyl group, an aryl group, an alkaryl group, an allyl group, aralkyl group, an alkenyl group, an alkynyl group, an alicyclic group, or a saturated or unsaturated heterocyclic group, at least one of R¹, R², R³ and R⁴ is an alkyl group having 1 to 8 carbon atoms, and R⁸, R⁹, R¹⁰ and R¹¹ each independently represents a hydrogen atom, an alkyl group, an aryl group, an allyl group, an alkaryl group, an aralkyl group, an alkenyl group, an alkynyl group, an alicyclic group, or a saturated or unsaturated heterocyclic group.

Among these, tetra n-butylammoniumtriphenylboron, tetra n-butylammoniumtrinaphthylboron, tetra n-butylammoniumtri(p-t-butylphenyl)boron, tetramethylammonium n-butyltriphenylboron, tetramethylammonium n-butyltrinaphthylboron, tetramethylammonium n-octyltriphenylboron, tetramethylammonium n-octyltrinaphthylboron, tetraethylammonium n-butyltriphenylboron, tetraethylammonium n-butyltrinaphthylboron, trimethylhydrogenammonium n-butyltriphenylboron, triethylhydrogenammonium n-butyltriphenylboron, tetrahydrogenammonium n-butyltriphenylboron, tetramethylammoniumtetra n-butylboron, tetraethylammoniumtetra n-butylboron, and tetraphenylboron can be used because a polymerization function is efficiently exhibited.

The organic boron compound can exhibit a function as a polymerization initiator by using it in combination with the photo-thermal converting material (for example, D⁺ A⁻) in the case of generating a radical (R.) by irradiation with infrared ray, as shown in the following scheme (5):

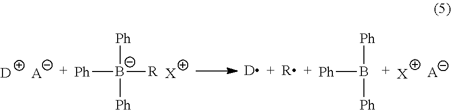

wherein Ph represents a phenyl group, R represents an alkyl group having 1 to 8 carbon atoms, and X⁺ represents an ammonium ion.

The content of the organic boron compound is preferably within a range from 0.1 to 15% by mass, and particularly preferably from 0.5 to 7% by mass, based on the solid content of the imaging layer. If the content of the organic boron compound is less than 0.1% by mass, an insufficient polymerization reaction can lead to poor curing and the resulting negative photosensitive lithographic printing plate has a weak image area. On the other hand, if the content of the organic boron compound is more than 15% by mass, the polymerization reaction may not efficiently occur. If necessary, at least two organic boron compounds (B) can be used in combination.

It is preferable that the heat-polymerization initiator be an onium salt.

An onium salt is a salt comprising a cation having at least one onium ion atom in the molecule, and an anion. Examples of the onium ion atom in the onium salt include S⁺ atom in sulfonium, I⁺ atom in iodonium, N⁺ in ammonium, P⁺ atom in phosphonium, and N₂⁺ in diazonium. Among these onium ion atoms, S⁺, I⁺ and N₂⁺ atoms are preferable. Examples of the structure of the onium salt include triphenylsulfonium, diphenyliodonium, diphenyldiazonium, and derivatives obtained by introducing an alkyl group and an aryl group into the benzene ring of these compounds, and derivatives obtained by introducing an alkyl group and an aryl group into the benzene ring of these compounds.

Examples of the anion of the onium salt include halogen anion, ClO₄⁻, PF₆⁻, BF₄⁻, SbF₆⁻, CH₃SO₃⁻, CF₃SO₃⁻, C₆H₅SO₃⁻, CH₃C₆H₄SO₃⁻, HOC₆H₄SO₃⁻, ClC₆H₄SO₃⁻, and boron anion represented by the above formula (2).

The onium salt can be obtained by combining an onium salt having S⁺ in the molecule with an onium salt having r in the molecule in view of sensitivity and storage stability. In view of sensitivity and storage stability, the onium salt can be a polyvalent onium salt having at least two onium ion atoms in the molecule. At least two onium ion atoms in the cation are bonded through a covalent bond. Among polyvalent onium salts, those having at least two onium ion atoms in the molecule are useful and those having S⁺ and I⁺ in the molecule are particularly useful. Representative polyvalent onium salts are represented by the following formulas (6) and (7):

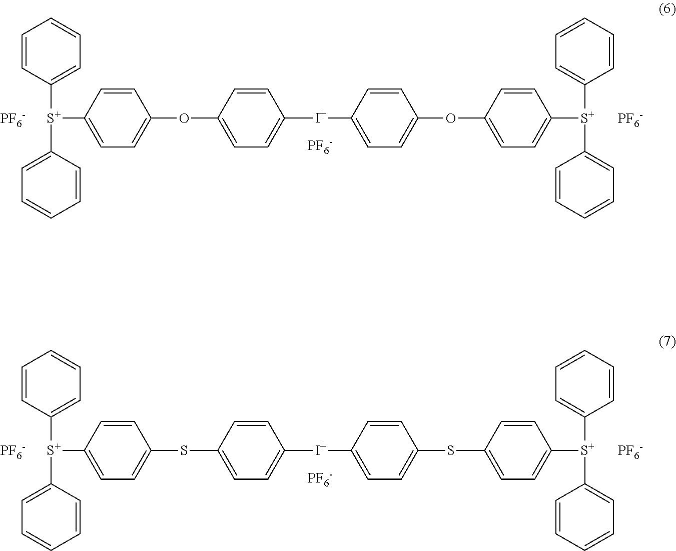

Furthermore, the onium salts described in paragraphs [0033] to [0038] of the specification of JP-A-2002-082429 or the iodonium borate complexes described in paragraphs [0097] to [0049] of the specification of JP-T-2009-538446 (cf. page 9, line 3 to page 12, line 23 of WO 2007/139687) can also be used in the present invention.

According to an embodiment of the present invention, the photo-thermal converting material as explained below absorbs IR and converts the absorbed IR to heat. An onium salt is decomposed by the generated heat thereby to form radicals. Due to the formed radicals, the chain polymerization of the radical-polymerizable compound(s) proceeds to cure or to harden the exposed portions of the imaging layer.

The content of the onium salt is preferably within a range from 0.1 to 25% by mass, and particularly preferably from 1.0 to 15% by mass, based on the solid content of the imaging layer or the composition for preparing the imaging layer. If the content of the onium salt is less than 0.1% by mass, the resulting negative photosensitive lithographic printing plate may be insufficient with respect to sensitivity and printing durability because of insufficient polymerization reaction. On the other hand, if the content of the onium salt is more than 25% by mass, the resulting negative photosensitive lithographic printing plate may be inferior with respect to the developing properties. If necessary, at least two onium salts can be used in combination. Also a polyvalent onium salt can be used in combination with a monovalent onium salt.

As the photo-polymerization initiator, triazine-based compound(s) is/are preferable. These photo-polymerization initiators can be used alone or in combination.

The triazine-based compound is a known polymerization initiator which is used in radical polymerization. For example, bis(trihalomethyl)-s-triazine can be preferably used as the photo-polymerization initiator.

The amount of the triazine-based compound is usually a small amount. If the amount is too large, this may lead to unsatisfactory results because the triazine-based compound causes sensitivity reduction and is crystallized and reprecipitated in the photosensitive layer after coating. The content of the triazine-based compound is preferably within a range from 0.1 to 15% by mass based on the solid content of the imaging layer or the composition for preparing the imaging layer. If the amount is within a range from 0.5 to 7% by mass, good results are obtained.

To the photo-polymerization initiator, optional accelerators, for example, a mercapto compound such as mercapto-3-triazole, and an amine compound, can be added.

If a polymerization initiator other than the organic boron compounds, onium salts and triazine-based compounds is used, the polymerization initiator can be present in the imaging layer or the composition for preparing the imaging layer in an amount within the range from 0.001 to 20% by mass, preferably from 0.01 to 10% by mass, and more preferably from 0.1 to 5% by mass, based on the solid content of the imaging layer or the composition for preparing the imaging layer.

### Photo-Thermal Converting Material

It is preferable that the radical polymerization initiator comprises at least one photo-thermal converting material.

In the present specification, the photo-thermal converting material means any material capable of converting electromagnetic waves into thermal energy and is a material having a maximum absorption wavelength within the near infrared or infrared range, for example, a material having a maximum absorption wavelength within a range from 760 to 1,200 nm. Examples of such a substance include various pigments and dyes.

The pigments used in the present invention are commercially available pigments described, for example, in “Color Index Handbook,” “Latest Pigment Handbook” (edited by Nihon Pigment Technique Society, published in 1977), “Latest Pigment Application Technique” (published by CMC in 1986), and “Printing Ink Technique” (published by CMC in 1984). Applicable types of pigments include black, yellow, orange, brown, red, violet, blue and green pigments, fluorescent pigments and polymer-grafted dyes. For example, the following can be used: insoluble azo pigments, azo lake pigments, condensed azo pigments, chelated azo pigments, phthalocyanine pigments, anthraquinone pigments, perylene and perinone pigments, thiomindigo pigments, guinacridone pigments, dioxazine pigments, isoindolinone pigments, quinophthalone pigments, lake pigments, azine pigments, nitroso pigments, nitro pigments, natural pigments, fluorescent pigments, inorganic pigments, and carbon black.

Among these pigments, carbon black is preferably used as a material which efficiently absorbs light in the near infrared or infrared range and is also economically superior. As the carbon black, grafted carbon blacks having various functional groups which are excellent in dispersibility and commercially available are preferable, and examples thereof include those described on page 167 of “The Carbon Black, Handbook, 3rd edition” (edited by the Carbon Black Society of Japan and issued in 1995) and those described on page 111 of “Characteristics, Optimum Blending and Applied Technique of Carbon Black” (edited by Technical Information Society in 1997), all of which are preferably used in the present invention.

These pigments can be used without surface treatment, or they can be used after being subjected to a surface treatment. As a method of surface treatment, mention can be made of a method of surface-coating a resin or a wax, a method of attaching a surfactant, and a method of binding a reactive substance (e.g. silane coupling agent, epoxy compound, polyisocyanate etc.) to the surface of a pigment. The above-mentioned surface treatment methods are described in “Property and Application of Metal Soap” (Saiwai Shobou), “Printing Ink Technique” (published by CMC in 1984) and “Latest Pigment Application Technique” (published by CMC in 1986). The particle size of these pigments is preferably within a range from 0.01 to 15 μm, and more preferably from 0.01 to 5 μm.

The dyes used in the present invention are conventionally known commercially available dyes described, for example, in “Dye Handbook” (edited by the Association of Organic Synthesis Chemistry, published in 1970), “Handbook of Color Material Engineering” (edited by the Japan Society of Color Material, Asakura Shoten K. K., published in 1989), “Technologies and Markets of Industrial Dyes” (published by CMC in 1983), and “Chemical Handbook, Applied Chemistry Edition” (edited by The Chemical Society of Japan, Maruzen Shoten K. K., published in 1986). Specific examples of the dyes include azo dyes, azo dyes in the form of metal complex salts, pyrazolone azo dyes, anthraquinone dyes, phthalocyanine dyes, carbonium dyes, quinonimine dyes, methine dyes, cyanine dyes, indigo dyes, quinoline dyes, nitro-based dyes, xanthene-based dyes, thiazine-based dyes, azine dyes, and oxazine dyes.

As the dyes capable of efficiently absorbing near infrared rays or infrared rays, for example, the following dyes can be used: azo dyes, metal complex azo dyes, pyrazolone azo dyes, naphthoquinone dyes, anthraquinone dyes, phthalocyanine dyes, carbonium dyes, quinoneimine dyes, methine dyes, cyanine dyes, squalirium dyes, pyrylium salts, and metal thiolate complexes (for example, nickel thioate complexes). Among these, cyanine dyes are preferable, and examples thereof are the cyanine dyes represented by the general formula (I) of JP-A-2001-305722 and the compounds described in paragraphs [0096] to [0103] of JP-A-2002-079772.

In particular, as the dyes, a near infrared radiation absorbing cationic dye represented by the formula shown below is preferable since it enables a heat-polymerization initiator to efficiently exert a polymerization function:

D⁺A⁻

wherein
D⁺ represents a cationic dye absorbing in a near infrared range, and
A⁻ represents an anion.

Examples of the cationic dye absorbing in a near infrared range include a cyanine-based dye, a triarylmethane-based dye, an aminium-based dye, and a diimmonium-based dye, each absorbing in a near infrared range. Specific examples of a cationic dye absorbing in a near infrared range include those shown below.

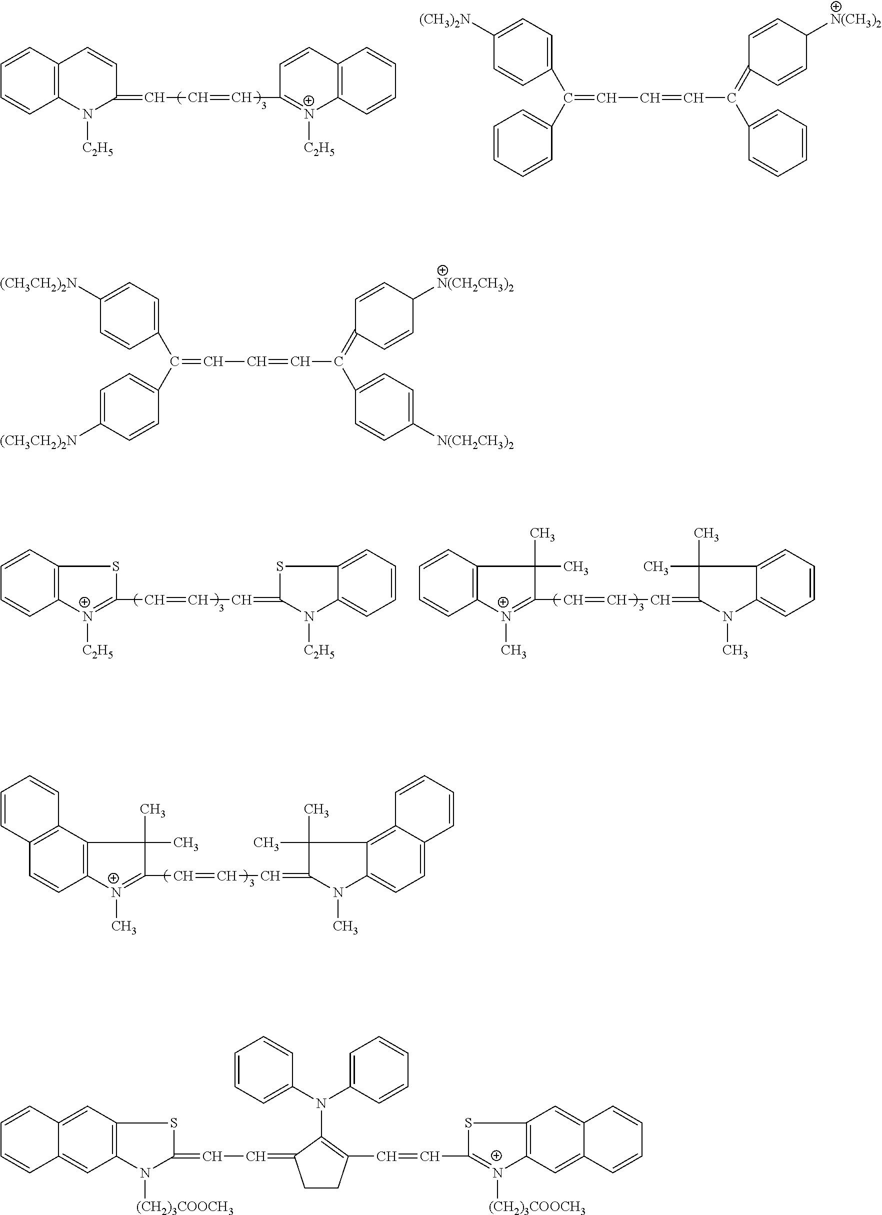

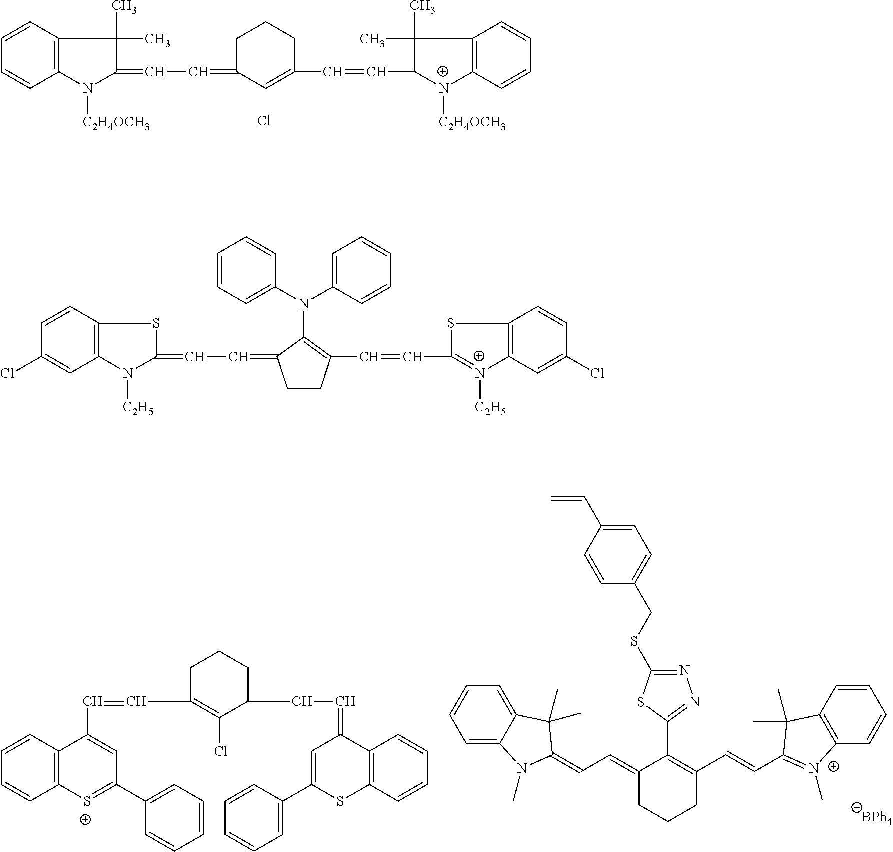

Examples of the anion include a halogen anion, ClO₄⁻, PF₆⁻, BF₄⁻, SbF₆⁻, CH₃SO₃⁻, CF₃SO₃⁻, C₆H₅SO₃⁻, CH₃C₆H₄SO₃⁺, HOC₆H₄SO₃⁻, ClO₆H₄SO₃⁻, and a boron anion represented by the following formula (3). The boron anion is preferably a triphenyl n-butylboron anion, a tri-naphthyl n-butylboron anion and a tetraphenyl boron anion.

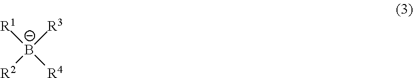

wherein
R¹, R², R³ and R⁴ independently denote an alkyl group, an aryl group, an aralkyl group, alkenyl group, an alkynyl group, an alicyclic group, or a saturated or unsaturated heterocyclic group.

As the photo-thermal converting material, the cyanine dye represented by the following chemical formula is useful.

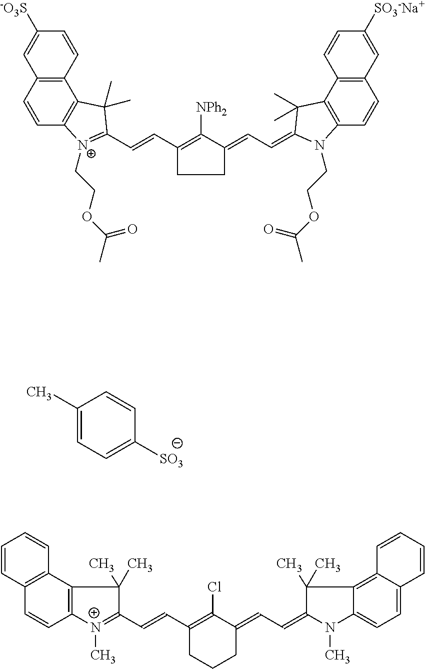

The photo-thermal converting material can be present in the imaging layer or the composition for preparing the imaging layer in an amount within the range from 0.001 to 20% by mass, preferably from 0.01 to 10% by mass, and more preferably from 0.1 to 5% by mass, based on the solid content of the imaging layer or the composition for preparing the imaging layer. If the amount is less than 0.001% by mass, sensitivity may decrease. On the other hand, if the amount is more than 20% by mass, the non-image area may be contaminated during printing. These photo-thermal converting materials can be used alone or in combination.

### Polymer Particles

The composition for preparing the imaging layer of the lithographic printing plate precursor according to the present invention includes at least one polymer particle which has an average particle diameter of 300 nm or more, and comprises two or more types of poly(alkyleneoxide) moieties. Two or more polymer particles can be present. Due to the polymer particle(s), the permeability of water into the imaging layer is enhanced, and therefore, the on-press developability is enhanced.

The average particle diameter of the polymer particle is not limited as long as it is 300 nm or more. It is preferable that the average particle diameter thereof is 300 to 2000 nm, more preferable 320 to 1500 nm, and even more preferable 340 to 1200 nm. It is preferable that the minimum particle size of the polymer particle be 100 nm or more, more preferably 140 nm or more, and even more preferably 170 nm or more. It is preferable that the maximum particle size of the polymer particle be 900 nm or less, more preferably 800 nm or less, and even more preferably 700 nm or less.

The average particle diameter or size can be measured with a conventional measurement device based on a laser-diffraction or distribution principle. The term “average particle diameter” herein means a volume average particle diameter measured with a laser diffraction particle size analyzer.

The polymer particle can be in the form of an aggregate (secondary particle) of primary particles. In this case, the average particle diameter of the primary particle can be less than 300 nm, and can be, for example, from about 100 to about 200 nm, preferably from about 120 to about 190 nm, and more preferably from about 130 nm to about 180 nm. In this case, the average particle diameter of the polymer particle means an average size (average diameter) of the aggregates (secondary particle).

The polymer (hereafter, referred to as simply “polymer”) constituting the polymer particle comprises a plurality of structural units having a single type of a pendant group including two or more types of poly(alkyleneoxide) moieties; a plurality of structural units having two or more types of pendant groups each of which includes each of two or more types of poly(alkyleneoxide) moieties; or a plurality of structural units having two or more types of pendant groups including two or more types of poly(alkyleneoxide) moieties. It is preferable that the polymer constituting the polymer particle comprises a plurality of structural units having two or more types of pendant groups each of which includes each of two or more types of poly(alkyleneoxide) moieties. In this case, each pendant group includes a single type of poly(alkyleneoxide) moiety. In general, most of the pendant group is a poly(alkyleneoxide) moiety or moieties, but it can also include either a linking group other than the poly(alkyleneoxide) moiety or an end group other than the poly(alkyleneoxide) moiety, or it can include the both.

In some embodiments, the alkyleneoxide moiety is a (C₁-C₆) alkylene oxide group, and is typically a (C₁-C₄) alkylene oxide group. For example, the alkylene oxide moiety or segment can include a linear or branched alkylene oxide group having a 1 to 4 carbon atoms, such as —[CH₂O—], —[CH₂CH₂O—], —[CH(CH₃)O—], —[CH₂CH₂CH₂O—], —[CH(CH₃)CH₂O—], —[CH₂CH(CH₃)O—], —[CH₂CH₂CH₂CH₂O—], —[CH(CH₃)CH₂CH₂O—], —[CH₂CH(CH₃)CH₂O—], —[CH₂CH₂CH(CH₃)O-] or a substituted form thereof. In some embodiments, the poly(alkyleneoxide) moiety is composed of these constituent units. According to one embodiment, the poly(alkyleneoxide) moiety is composed of a —[CH₂CH₂—O-] constituent unit.

The poly(alkyleneoxide) unit typically includes in total 1 to 200, preferably 2 to 150, and more preferably 10 to 100 alkyleneoxide structural units. In general, the number average molecular weight (Mn) of the poly(alkyleneoxide) unit is about 300 to about 10,000, preferably from about 500 to about 5,000, and more preferably from about 1000 to 3,000.

A preferable pendant group including the poly(alkyleneoxide) moiety can have any of the following general formulae (1) through (4), and general formula (1) is:

—COO—[(CH₂)ₓ(CH(R¹))O]_{y}—R² (1)

general formula (2) is:

—COO—[(CH(R¹))(CH₂)ₓO]_{y}—R² (2)

wherein in general formulae (1) and (2),
x is an integer from 1 to 5,
y is an integer from 1 to 400,
R¹ independently denotes a hydrogen atom or a methyl group, and
R² denotes a hydrogen atom or a monovalent hydrocarbon group having 1 to 8 carbon atoms, general formula (3) is:

—COO—[(CH₂)_{z}(CH(R³))O]ₘ—[(CH₂)ₙ(CH(R⁴)O]_{q}—R⁵ (3)

and general formula (4) is:

—COO—[(CH(R³))(CH₂)_{z}O]ₘ—[(CH(R⁴))(CH₂)_{b}O]_{q}—R⁵ (4)

wherein in general formulae (3) and (4),
each of n and z is independently an integer from 1 to 5,
each of m and q is independently an integer from 1 to 200,
R³ and R⁴ independently denotes a hydrogen atom or a methyl group, provided that R³ and R⁴ are different if n and z are the same number, and
R⁵ denotes a hydrogen atom or a monovalent hydrocarbon group having 1 to 8 carbon atoms.

As the monovalent hydrocarbon group having 1 to 8 carbon atoms, mention can be made of an alkyl group such as a methyl group, an ethyl group, a propyl group, a butyl group, a pentyl group, a hexyl group, a heptyl group, and an octyl group; a cycloalkyl group such as a cyclopentyl group and a cyclohexyl group; an alkenyl group such as a vinyl group, an allyl group and a butenyl group; an aryl group such as a phenyl group and tolyl group; an aralkyl group such as a benzyl group; and a group in which at least a part of the hydrogen atom(s) of the above group is/are substituted with a halogen atom such as a fluorine, or an organic group including an epoxy group, a glycidyl group, an acyl group, a carboxy group, an amino group, a methacryl group, and a mercapto group, with the proviso that the total number of carbon atoms is 1 to 8.

A specific example of a suitable pendant group comprising the poly(alkyleneoxide) moiety has the following formula:

—C(—O)O—(CH₂CH₂O)_{y}—CH₃

wherein
y is from about 10 to about 100, and more preferably from about 25 to about 75. According to one embodiment, y is from about 40 to about 50.

The polymer can be characterized by a number average molecular weight (Mn) of preferably from about 10,000 to about 250,000, more preferably from 25,000 to 200,000.

The polymer can function as a binder, is generally a solid at room temperature, and is typically a non-elastomeric thermoplastic. The polymer comprises both hydrophilic and hydrophobic regions. Although not bound by any theory, the combination of hydrophilic and hydrophobic regions is thought to be important for enhancing differentiation of the exposed and unexposed areas, to facilitate developability.

The polymer can be an addition polymer or a condensation polymer. Addition polymers can be prepared from, for example, acrylate esters and methacrylate esters, acrylic and methacrylic acid, methyl methacrylate, allyl acrylate and allyl methacrylate, acrylamides and methacrylamides, acrylonitrile and methacrylonitrile, styrene, hydroxystyrene, or a combination thereof. Suitable condensation polymers include polyurethanes, epoxy resins, polyesters, polyamides, and phenolic polymers, including phenol/formaldehyde and pyrogalloWacetone polymers.

The polymer preferably includes a hydrophobic main chain (backbone) including structural units having attached pendant groups. In some embodiments, the hydrophobic main chain is an all-carbon main chain, such as where the polymer is a copolymer derived from a combination of ethylenically unsaturated monomers. In other embodiments, the hydrophobic main chain can include heteroatoms, such as where the polymer is formed by a condensation reaction or some other means.

Specifically, it is preferable that the polymer with two or more poly(alkyleneoxide) moieties be a polymer having a main chain which comprises no poly(alkyleneoxide) moiety, and

two or more pendant groups comprising the two or more types of poly(alkyleneoxide) moieties.

The phrase “comprises no poly(alkyleneoxide) moiety” means that no poly(alkyleneoxide) is present in the main chain. The main chain is preferably hydrophobic, and the pendant group is preferably hydrophilic.

For example, the polymer can be at least derived from at least two selected from the group consisting of poly(alkyleneglycol)alkylether(meth)acrylates and poly(alkyleneglycol)(meth)acrylates.

It is preferable that the polymer includes a plurality of constitutional units having pendant cyano groups (—C≡N) attached directly to the hydrophobic main chain. By way of example only, constitutional units having pendant cyano groups include —[CH₂CH(C≡N)—] and —[CH₂C(CH₃)(C≡N)—].

Constitutional units having pendant cyano groups can be derived from ethylenically unsaturated monomers such as acrylonitrile or methacrylonitrile, for example, or from a combination thereof. As used herein, the term “(meth)acrylonitrile” indicates that either acrylonitrile or methacrylonitrile, or a combination of acrylonitrile and methacrylonitrile, is suitable for the stated purpose.

In some embodiments of the invention, the polymer is a copolymer derived from (meth)acrylonitrile as one co-monomer. However, constitutional units having pendant cyano groups can also be introduced into the polymer by other conventional means. By way of example, the polymer can be a copolymer derived from a cyanoacrylate monomer, such as methyl cyanoacrylate or ethyl cyanoacrylate. In an alternative embodiment, the polymer can be derived from a combination of (meth)acrylonitrile and a cyanoacrylate monomer.

In a particular embodiment of the invention, the main chain of the polymer can also comprise constitutional units derived from other suitable polymerizable monomers or oligomers. For example, the polymer can comprise constitutional units derived from acrylate esters, methacrylate esters, styrene, hydroxystyrene, acrylic acid, methacrylic acid, methacrylamide, or a combination of any of the foregoing. Especially suitable are constitutional units derived from styrene or methacrylamide. Also suitable are constitutional units derived from methyl methacrylate or allyl methacrylate. In particular, constitutional units having pendant unsubstituted or substituted phenyl groups attached directly to the hydrophobic main chain can be useful. Substituted phenyl groups include, for example, 4-methylphenyl, 3-methylphenyl, 4-methoxyphenyl, 4-cyanophenyl, 4-chlorophenyl, 4-fluorophenyl, 4-acetoxyphenyl, and 3,5-dichlorophenyl. Such constitutional units can be derived from styrene or substituted styrenic monomers, for instance.

In some embodiments, the polymer includes constitutional units having pendant groups that contain siloxane functionality. Suitable polymers and the preparation thereof are described in U.S. Pat. No. 7,045,2171, entitled “On-Press Developable Imageable Element” (incorporated by reference herein in its entirety).

In the polymer for the practice of the present invention, a large percentage of the total recurring units can include pendant cyano groups. Generally from about 70 to about 99.9% by mass, and typically from about 75 to about 95% by mass, of the total constitutional units in this polymer can include pendant cyano groups attached directly to the hydrophobic main chain. This polymer can include only a small fraction of constitutional units having two or more pendant groups including two or more types of poly(alkylene oxide) moieties. Generally from about 0.1 to about 20% by mass, and typically from about 1 to about 10% by mass, of the total constitutional units in this polymer can have two or more pendant groups including two or more poly(alkylene oxide) moieties. When included, a minor fraction of the total constitutional units of this polymer can be derived from other monomers (such as styrene, acrylonitrile, etc.). Generally from 0 to about 10% by mass, typically from about 1 to about 8% by mass, and more suitably from about 2 to about 5% by mass, of the total constitutional units in this polymer can be derived from other monomers.

In one embodiment, the polymer is a random copolymer consisting essentially of:

i) constitutional units having a pendant cyano group attached directly to the hydrophobic main chain;
ii) constitutional units having pendant groups including two or more types of poly(alkylene oxide) moieties; and
iii) constitutional units having pendant unsubstituted or substituted phenyl groups attached directly to the hydrophobic main chain.

In another embodiment, the polymer is a random copolymer consisting essentially of:

i) constitutional units of the form —[CH₂C(R)(C≡N)—];
ii) constitutional units of the form —[CH₂C(R)(PEO)—], wherein PEO represents two or more pendant groups of the form —C(═O)O—[CH₂CH₂O-]_{y}CH₃, wherein y is in the range from about 25 to about 75; and
iii) constitutional units of the form: —[CH₂CH(Ph)-]; wherein each R independently represents —H or —CH₃, and Ph represents a pendant phenyl group.

In yet another embodiment, the polymer is a random copolymer in which about 70 to about 99.9% by mass of the total constitutional units in the random copolymer are of the form —[CH₂C(R)(C≡N)—]; about 0.1 to about 20% by mass of the total constitutional units in the random copolymer are constitutional units of the two or more forms of —[CH₂C(R)(PEO)—]; and about 2 to about 10% by mass of the total constitutional units in the random copolymer are of the form —[CH₂CH(Ph)-].

The polymer is typically a random copolymer obtained by a free-radical copolymerization of co-monomers. In a typical preparation, a mixture of at least three co-monomers, one that is a precursor of the constitutional units having at least one group selected from the group consisting of a pendent cyano group, a pendant aryl group and a pendant amido group, and others that are precursors of the constitutional units having pendant groups including two or more types of poly(alkylene oxide) moieties (more properly termed a “macromer”), are co-polymerized. As used herein, the phrases “mixture of monomers” and “combination of monomers” are used for simplicity to include a mixture or combination of one or more polymerizable monomers or a mixture or combination of one or more polymerizable macromers, or a mixture or combination of both of one or more polymerizable monomers and one or more polymerizable macromers.

Thus, it is preferable that the polymer further have at least one group selected from the group consisting of a cyano group, an aryl group and an amide group.

In this case, the polymer can be at least derived from at least two selected from the group consisting of poly(alkyleneglycol)alkylether(meth)acrylates and poly(alkyleneglycol)(meth)acrylates, and (meth)acrylonitrile, styrene, (meth)acrylamide or a combination thereof.

By way of example only, the polymer of these embodiments can be formed by polymerization of a combination or mixture of suitable monomers/macromers, such as:

A) acrylonitrile, methacrylonitrile, or a combination thereof (i.e., “(meth)acrylonitrile”);
B) poly(alkylene glycol)esters of acrylic acid or methacrylic acid, such as poly(ethylene glycol)methyl ether acrylate, poly(ethylene glycol)methyl ether methacrylate, or a combination thereof (i.e., “poly(ethylene glycol)methyl ether(meth)acrylate”); and
C) optionally, monomers such as styrene, acrylamide, methacrylamide, etc., or a combination of suitable monomers.

Precursors useful as macromer B include at least two selected from the group consisting of, for example, polyethylene glycol monomethacrylate, polypropylene glycol methyl ether methacrylate, polyethylene glycol ethyl ether methacrylate, polyethylene glycol butyl ether methacrylate, polypropylene glycol hexyl ether methacrylate, polypropylene glycol octyl ether methacrylate, polyethylene glycol methyl ether acrylate, polyethylene glycol ethyl ether acrylate, polyethylene glycol phenyl ether acrylate, polypropylene glycol monoacrylate, polypropylene glycol monomethacrylate, polypropylene glycol methyl ether methacrylate, polypropylene glycol ethyl ether methacrylate, polypropylene glycol butyl ether methacrylate, (polyethylene glycol/propylene glycol) methylether methacrylate, (polyethyleneglycol/polytetramethyleneglycol) methylether methacrylate, (polyethyleneglycol/polytetramethyleneglycol) methacrylate, poly(vinyl alcohol) monomethacrylate, poly(vinyl alcohol) monoacrylate, and a mixture thereof. Precursors commonly used as monomer B include a combination of at least two selected from the group consisting of poly(ethyleneglycol) methylether methacrylate, poly(ethyleneglycol) monoacrylate, poly(propyleneglycol) methylether methacrylate, (polyethyleneglycol/polytetramethyleneglycol) methacrylate, and poly(propyleneglycol) monomethacrylate. As used herein, the term “(meth)acrylate” with respect to a polymerizable macromer indicates that either an acrylate macromer or a methacrylate macromer, or a combination of acrylate macromers and methacrylate macromers, is suitable for the stated purpose. Also, the phrase “alkyl ether” with respect to a macromer indicates a lower alkyl ether, generally a (C_{1-C6}) linear or branched saturated alkyl ether, such as, e.g., a methyl ether or ethyl ether.

Suitable monomers that can be used as optional monomer C include, for example, acrylic acid, methacrylic acid, acrylate esters, methacrylate esters such as methyl methacrylate, allyl methacrylate, hydroxyethyl methacrylate, styrene, hydroxystyrene, methacrylamide, or a combination of any of the foregoing. Especially suitable monomers are styrene or methacrylamide, or monomers derived therefrom. Specific examples of suitable monomers include styrene, 3-methyl styrene, 4-methyl styrene, 4-methoxy styrene, 4-acetoxy styrene, alpha-methyl styrene, acrylic acid, methyl acrylate, ethyl acrylate, butyl acrylate, n-hexyl acrylate, methacrylic acid, methyl methacrylate, ethyl methacrylate, n-propyl methacrylate, n-butyl methacrylate, n-pentyl methacrylate, neo-pentyl methacrylate, cyclohexyl methacrylate, n-hexyl methacrylate, 2-ethoxyethyl methacrylate, 3-methoxypropyl methacrylate, allyl methacrylate, vinyl acetate, vinyl butyrate, methyl vinyl ketone, butyl vinyl ketone, vinyl fluoride, vinyl chloride, vinyl bromide, maleic anhydride, maleimide, N-phenyl maleimide, N-cyclohexyl maleimide, N-benzyl maleimide, and mixtures thereof.

By way of example, the polymer described above can be prepared by free radical polymerization. Free radical polymerization is well known to those skilled in the art and is described, for example, in Chapters 20 and 21 of Macromolecules, Vol. 2, 2nd Ed., H. G. Elias, Plenum, New York, 1984. Useful free radical initiators are peroxides such as benzoyl peroxide, hydroperoxides such as cumyl hydroperoxide, and azo compounds such as 2,2′-azobisisobutyronitrile (AIBN). Chain transfer agents, such as dodecyl mercaptan, can be used to control the molecular weight of the compound.

In one embodiment, the polymer is a copolymer derived from a combination of polymerizable monomers that includes at least 50% by mass of monomer A.

In another embodiment, the polymer is a copolymer derived from: about 55 to about 90% by mass of (meth)acrylonitrile; about 5 to about 15% by mass of one of poly(ethyleneglycol)alkyl ether(meth)acrylate, poly(propyleneglycol) mono(meth)acrylate, and (polyethyleneglycol/polytetramethyleneglycol) methacrylate; and about 5 to about 30% by mass of styrene. In yet another embodiment, the polymer is a copolymer derived from a combination of monomers consisting essentially of: about 55 to about 90% by mass of (meth)acrylonitrile; about 5 to about 15% by mass of one of poly(ethyleneglycol) alkyl ether(meth)acrylate, poly(propyleneglycol) mono(meth)acrylate, and (polyethyleneglycol/polytetramethyleneglycol) methacrylate; and about 5 to about 30% by mass of styrene. In still another embodiment, the polymer is a copolymer derived from a combination of monomers consisting essentially of: about 55 to about 90% by mass of acrylonitrile; about 5 to about 15% by mass of one of poly(ethyleneglycol) methylether methacrylate, poly(propyleneglycol) mono(meth)acrylate, and (polyethyleneglycol/polytetramethyleneglycol) methacrylate; and about 5 to about 30% by mass of styrene.

Suitable solvents for free radical polymerization include liquids that are inert to the reactants and which will not otherwise adversely affect the reaction, for example, esters such as ethyl acetate and butyl acetate; ketones such as methyl ethyl ketone, methyl isobutyl ketone, methyl propyl ketone, and acetone; alcohols such as methanol, ethanol, isopropyl alcohol, and butanol; ethers such as dioxane and tetrahydrofuran; and mixtures thereof.

However, the polymer is preferably prepared in hydrophilic medium (water or mixtures of water and alcohol), which can facilitate the formation of particles dispersed in the solvent. Furthermore, it can be desirable to conduct the polymerization in a solvent system that does not completely dissolve the monomer(s) that result in constitutional units that provide hydrophobic character to the polymer main chain or backbone, such as acrylonitrile or methacrylonitrile. By way of example, the polymer can be synthesized in a water/alcohol mixture, such as a mixture of water and n-propanol.

All monomers/macromers and polymerization initiators can be added directly to the reaction medium, with the polymerization reaction proceeding at an appropriate temperature determined by the polymerization initiator chosen. Alternatively, the macromers containing the poly(alkylene oxide) moieties may can be added to a reaction solvent first, followed by the slow addition of monomers at an elevated temperature. The initiator can be added to a monomer mixture, or to a solution of macromer, or both.

Although preparation of the polymer has been described in terms of monomers and macromers that can be used to form the co-polymer, practice of the invention is not limited to the use of copolymers formed by polymerization of a mixture of co-monomers. The polymer can be formed by other routes that will be apparent to those skilled in the art, such as by modification of precursor polymers. In some embodiments, the polymer can be prepared as a graft copolymer, such as where two or more poly(alkyleneoxide) moieties are grafted onto a suitable polymeric precursor. Such grafting can be done, for example, by anionic, cationic, non-ionic, or free radical grafting methods.

By way of example only, the polymer can be prepared by first copolymerizing a suitable combination of polymerizable monomers to produce a graftable copolymer, and thereafter grafting functional groups comprising two or more poly(alkylene oxide) moieties onto the graftable copolymer. For instance, a graft copolymer can be prepared by reacting two or more hydroxy-functional or amine functional polyethylene glycol monoalkyl ethers with a polymer having co-reactive groups, including acid chloride, isocyanate or anhydride groups. Other methods of preparation of the graft copolymers suitable for use in the present invention include the methods described in U.S. Pat. No. 6,582,882.

The polymer particle(s) can be present in the composition for preparing the imaging layer in an amount within the range from 1 to 60% by mass, preferably from 10 to 50% by mass, and more preferably from 20 to 40% by mass, based on the solid content of the composition for preparing the imaging layer.

The polymer particle can be present in the imaging layer in an amount of 1 to 60% by mass, preferably from 10 to 50% by mass, and more preferably from 20 to 40% by mass, based on the solid content of the imaging layer.

If the polymer particle is in the form of an aggregate of primary particles, it is possible that the imaging layer according to the present invention can include primary particles with an average particle diameter of less than 300 nm. The primary particle can be present as it is or in the form of aggregates, or both. It is preferable that the polymer particles and the primary particles thereof with an average particle diameter distributed in a range of from 120 to 400 nm be present in the imaging layer in an amount of 20 to 60% by mass, preferably 25 to 50% by mass, relative to the solid content of the imaging layer.

### Other Constituent Components of Imaging Layer or Composition for Preparing Imaging Layer

To the imaging layer or the composition for preparing the imaging layer of the lithographic printing plate precursor according to the present invention, if necessary, co-binder(s) and known additives such as colorants (dyes, pigments), surfactants, plasticizers, stability modifiers, development accelerators, polymerization inhibitors, printing agents, and lubricants (silicone powder) can be added.

Typical co-binders are water-soluble or water-dispersible polymers, such as, cellulose derivatives such as carboxymethyl cellulose, methylcellulose, hydroxypropyl methylcellulose, hydroxypropyl cellulose, hydroxyethyl cellulose; polyvinyl alcohol; polyacrylic acid; polymethacrylic acid; polyvinyl pyrrolidone; polylactide; polyvinyl phosphonic acid; synthetic co-polymers, such as the copolymer of an alkoxy polyethylene glycol acrylate or methacrylate, for example methoxy polyethylene glycol acrylate or methacrylate, with a monomer such as methyl methacrylate, methyl acrylate, butyl methacrylate, butyl acrylate, or allyl methacrylate; and mixtures thereof.

In some embodiments, the co-binder provides crosslinkable sites. For example, the crosslinkable sites can be ethylenically unsaturated sites.

Examples of preferable dyes include basic oil-soluble dyes such as Crystal Violet, Malachite Green, Victoria Blue, Methylene Blue, Ethyl Violet and Rhodamine B. Examples of commercially available dyes include “Victoria Pure Blue BOH” [manufactured by HODOGAYA CHEMICAL Co., Ltd.], “Oil Blue #603” [manufactured by Orient Chemical Industries, LTD.], “VPB-Naps (naphthalenesulfonate of Victoria Pure Blue)” [manufactured by HODOGAYA CHEMICAL Co., Ltd.] and “D11” [manufactured by PCAS Co.]; and pigments such as Phthalocyanine Blue, Phthalocyanine Green, Dioxadine Violet, and Quinacridone Red.

As the colorants, a color changing agent or a color changing system capable of generating a color change upon exposure can be used. By using this, it can be facilitated to make a distinction between exposed and non-exposed regions on the imaging layer. Examples of the color changing agent or system include (i) triarylmethane-based compounds, (ii) diphenylmethane-based compounds, (iii) xanthene-based compounds, (iv) thiazine-based compounds and (v) spiropyran-based compounds, and specific examples thereof include those described in JP-A-S58-27253. In particular, (i) triarylmethane-based color formers and (iii) xanthene-based color formers are preferred, because fogging less occurs and high color density is obtained.

Specific examples thereof include Crystal Violet Lactone, Malachite Green Lactone, Benzoyl Leuco Methylene Blue, 3-(N,N-diethylamino)-6-chlor-o-7-(β-ethoxyethylamino)fluoran, 3-(N,N,N-triethylamino)-6-methyl-7-a-nilinofluoran, 3-(N,N-diethylamino)-7-chloro-7-o-chlorofluoran, 2-(N-phenyl-N-methylamino)-6-(N-p-tolyl-N-ethyl)aminofluoran, 2-anilino-3-methyl-6-(N-ethyl-p-toluidino)fluoran, 3,6-dimethoxyfluoren, 3-(N,N-diethylamino)-5-methyl-7-(N,N-dibenzylamino)fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino)fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran 3,3-bis(1-ethyl-2-methylindol-3-yl)phthalide, 3,3-bis(1-n-butyl-2-methylindol-3-yl)phthalide, 3,3-bis(p-dimethylaminophenyl)-6-dimethylaminophthalide, 3-(4-diethylamino-2-ethoxyphenyl)-3-(1-ethyl-2-methylindol-3-yl)-4-phthalide, and 3-(4-diethylaminophenyl)-3-(1-ethyl-2-methylindol-3-yl)phthalide. These compounds are used individually or as a mixture.

Examples of surfactants include fluorine-based surfactants and silicone-based surfactants.

Examples of plasticizers include diethyl phthalate, dibutyl phthalate, dioctyl phthalate, tributyl phosphate, trioctyl phosphate, tricresyl phosphate, tri(2-chloroethyl) phosphate, and tributyl citrate.

As the stabilizer, for example, phosphoric acid, phosphorous acid, oxalic acid, tartaric acid, malic acid, citric acid, dipicolinic acid, polyacrylic acid, benzenesulfonic acid, and toluenesulfonic acid can be used in combination.

Examples of other stability modifiers include known phenolic compounds, quinones, N-oxide compounds, amine-based compounds, sulfide group-containing compounds, nitro group-containing compounds, and transition metal compounds. Specific examples thereof include hydroquinone, p-methoxyphenol, p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenimidazole, and N-nitrosoenylhydroxyamine primary cerium salts.

Examples of development accelerators include acid anhydrides, phenols and organic acids. The acid anhydrides are preferably cyclic anhydrides. For example, the following can be used as the cyclic acid anhydride: phthalic anhydride, tetrahydrophthalic anhydride, hexahydrophthalic anhydride, 3,6-endoxy-tetrahydrophthalic anhydride, tetrachlorophthalic anhydride, maleic anhydride, chloromaleic ahydride, α-phenyl maleic anhydride, succinic anhydride, and pyromellitic anhydride described in the description of U.S. Pat. No. 4,115,128. Examples of the non-cyclic acid anhydride include acetic anhydride. Examples of phenols include bisphenol A, 2,2′-bishydroxysulfone, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′,3″,4″-tetrahydroxy-3,5,3′,5′-tetramethyltriphenylmethane.

Examples of organic acids include sulfonic acids, sulfonic acids, alkylsulfuric acids, phosphonic acids, phosphate esters, and carboxylic acids described in JP-A-S60-88942 and JP-A-H02-96755, and specific examples thereof include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 4-dimethylaminobenzoic acid, 4-cyclohexene-1,2-dicarboxylic acid, erucic acid, lauric acid, n-undecanoic acid, and ascorbic acid.

Examples of polymerization inhibitors include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-tert-butylphenol), 3-mercapto-1,2,4-triazole, and N-nitroso-N-phenylhydroxylamine aluminum salt.

The amount of these various additives can vary depending on the purpose, but is preferably within a range from 0 to 30% by mass based on the solid content of the imaging layer or the composition for preparing the imaging layer. In the case of the multi-layer embodiments, the amount of these various additives is preferably within a range from 0 to 30% by mass relative to the total solid content of all the imaging layers.

In the imaging layer or the composition for preparing the imaging layer of the lithographic printing plate precursor of the present invention, alkali-soluble or dispersible resins may be used in combination, if necessary. Examples of the other alkali-soluble or dispersible resins include copolymers of alkali-soluble group-containing monomers such as acrylic acid, methacrylic acid, maleic acid, maleic anhydride, itaconic acid and itaconic anhydride and the other monomer(s), polyester resin and acetal resin.

### Preparation of Imaging Layer

The imaging layer of the lithographic printing plate precursor according to the present invention can be provided by applying, onto a substrate or an underlayer that can optionally be formed on the substrate, a composition containing the above components.

The above composition can include at least one solvent. Examples of the solvent used in the coating solution include ethylene dichloride, cyclohexanone, methyl ethyl ketone, methanol, ethanol, propanol, ethylene glycol monomethyl ether, l-methoxy-2-propanol, 2-methoxyethyl acetate, 1-methoxy-2-propyl acetate, dimethoxyethane, methyl lactate, ethyl lactate, N,N-dimethylacetoamide, N,N-dimethylformamide, tetramethylurea, N-methylpyrrolidone, dimethylsulfoxide, sulfolane, γ-butyrolatone, and toluene. When using a water soluble photosensitive layer, examples of the solvent are aqueous solvents such as water and alcohols. However, the solvent is not limited to these examples, and the solvent can be appropriately selected in accordance with physical properties of the imaging layer. These solvents are used alone or in the form of a mixture thereof. The concentration of the above-mentioned respective components (all solid contents including the additives) in the solvent is preferably from 1 to 50% by mass. It should be noted that the polymer in the polymer particles described above does not dissolve in the above solvent.

The composition amount (of all the solid contents) on the substrate after the solution is applied and dried varies depending on the use. Regarding a lithographic printing plate precursor, in general, the application amount is generally from 0.5 to 5.0 g/m². As the application amount gets smaller, the apparent sensitivity increases, but the membrane property of the recording layer gets worse. The composition applied on the substrate is usually dried at an elevated temperature. In order to dry within a short time, the lithographic printing plate precursor can be dried at 30 to 150° C. for 10 seconds to 10 minutes using a hot-air dryer or an infrared dryer.

The method of application can be any one selected from various methods, including roll coating, dip coating, air knife coating, gravure coating, gravure offset coating, hopper coating, blade coating, wire doctor coating, and spray coating.

### Other Layer(s)

The lithographic printing plate precursor of the present invention can include not only the imaging layer but also other layer(s) such as an underlayer, an overcoat layer, and a back coat layer in accordance with a desired property.

It is preferable that the overcoat layer be easily removable with a hydrophilic printing liquid, such as a fountain solution, during printing, and comprise one or more resins selected from hydrophilic organic polymer compounds. It is preferable that the hydrophilic organic polymer compound have a film-forming capability, and mention can be made of polyvinylacetate (with a rate of hydrolysis of 65% or more), polyacrylic acid amine salt, polyacrylic acid copolymer, an alkaline metal salt or an amine salt thereof, polymethacrylic acid, an alkaline metal salt or an amine salt thereof, polymethacrylic acid copolymer, an alkaline metal salt or an amine salt thereof, polyacrylamide or a copolymer thereof, polyhydroxyethylacrylate, polyvinylpyrrolidone, a copolymer thereof, polyvinylmethylether, vinylmethylether/maleic anhydride copolymer, poly-2-acrylamide-2-methyl-1-propansulfonic acid, an alkaline metal salt or an amine salt thereof, poly-2-acrylamide-2-methyl-1-propanesulfonic acid copolymer, an alkaline metal salt or an amine salt thereof, gum Arabic, fibrin derivatives (e.g., carboxymethylcellulose, carboxyethylcellulose, and methylcellulose), a modified one thereof, white dextrin, pullulan, and enzyme-decomposed etherified dextrin. Depending on purpose, it is possible to use two or more of the above resins by mixing them.

It is preferable that the dry amount of the applied overcoat layer be from 0.1 to 2.0 g/m². It is possible within this range to provide oxygen blocking from the imaging layer, preventing the contamination on the surface of the imaging layer with a lipophilic substance such as a stain derived from finger prints, or preventing a scratch on the surface of the imaging layer with nails.

Preferred examples of the back coat layer include layers made of an organic polymer compound described in JP-A-H05-45885 and coated layers made of a metal oxide obtained by hydrolyzing and polycondensating an organic or inorganic metal compound described in JP-A-H06-35174. Among these coated layers, particularly preferred is a layer made of the metal oxide obtained from an alkoxyl compound of silicon, such as Si(OCH₃)₄Si(OC₂H₅)₄, Si(OC₃H₇)₄ or Si(OC₄H₉)₄, which is inexpensive and easily available, because this coated layer is excellent in development resistance.

In the lithographic printing plate precursor according to the present invention, the imaging layer can be the top (outermost) layer. In other embodiments, it is preferable that an overcoat layer be present on the imaging layer. As the overcoat layer, an oxygen barrier layer which can prevent or reduce the contact of the imaging layer with oxygen.

As explained above, it is possible to prepare a lithographic printing plate precursor according to the present invention.

### Exposure

The lithographic printing plate precursor of the invention is imagewise exposed to light in accordance with properties of the imaging layer(s) thereof. Specific examples of the method of the exposure include light irradiation, such as irradiation of infrared ray with infrared laser, irradiation of ultraviolet ray with an ultraviolet lamp, irradiation of visible ray; electron beam irradiation such as γ-ray radiation; and thermal energy application with a thermal head, a heat roll, or a heating zone using a non-contact type heater or hot wind, or the like air. The lithographic printing plate precursor of the present invention can be used as a so-called computer-to-plate (CTP) plate capable of directly writing images on a plate, using a laser, based on digital image information from a computer. It is also possible to write images by a method using as a GLV (Grating Light Valve) or a DMD (Digital Mirror Device) as digital image writing means.

As a light source laser for exposure of the lithographic printing plate precursor of the present invention, a high-output laser having a maximum intensity within the near infrared or the infrared range is used most preferably. Examples of the high-output laser having a maximum intensity within a near infrared or infrared range include various lasers having a maximum intensity within a near infrared or infrared range of 760 to 3000 nm, for example, a semiconductor laser and a YAG laser. If necessary, a development treatment can be conducted after writing images on the photosensitive layer using laser and heat-treating in a heat oven.

### On-Press Development

The lithographic printing plate precursor according to the present invention can be transformed into a lithographic printing plate with image(s) by forming, writing image(s) in the imaging layer(s) as latent image(s) with a laser, and subjecting it to a developing process to remove non-image areas from the imaging layer(s).

It is possible to develop the lithographic printing plate precursor according to the present invention by mounting it directly on press after imaging or image-wise exposing, and contacting it with either ink, a fountain solution, or both of ink and a fountain solution during the initial impressions. Thus, the present invention also relates to a process for preparing a lithographic printing plate comprising a step of on press developing the lithographic printing plate precursor.

No separate development step is needed before mounting on press. This eliminates the separate development step along with both the processor and developer, thus simplifying the printing process and reducing the amount of expensive equipment required and chemical waste generated. Typical ingredients of aqueous fountain solutions, in addition to water, include pH buffering systems, such as phosphate and citrate buffers; desensitizing agents, such as dextrin, gum arabic, and sodium carboxymethylcellulose; surfactants and wetting agents, such as aryl and alkyl sulfonates, polyethylene oxides, polypropylene oxides, and polyethylene oxide derivatives of alcohols and phenols; humectants, such as glycerin and sorbitol; low boiling solvents such as ethanol and 2-propanol; sequestrants, such as borax, sodium hexametaphosphate, and salts of ethylenediamine tetraacetic acid; biocides, such as isothiazolinone derivatives; and antifoaming agents.

The temperature of the fountain solution range can be from 5° C. to 90° C., and more preferably from 10° C. to 50° C. The time for immersing range can be from 1 second to 5 minutes. If necessary, slight rubbing of the surface of the plate during development is possible.

The lithographic printing plate precursor according to the present invention can be subjected to on-press imaging or image-wise exposure. For on-press imaging, the lithographic printing plate precursor according to the present invention is imaged while mounted on a lithographic printing press cylinder, and the imaging layer is developed on-press with either a fountain solution, ink, or both a fountain solution and ink during the initial press operation. This method does not comprise a separate development step. This method is especially suitable for computer-to-press applications in which the lithographic printing plate precursor is directly imaged on the plate cylinder according to computer-generated digital imaging information, and with minimum or no treatment, directly prints out regular printed sheets. An example of a direct imaging printing press is the SPEEDMASTER 74-DI press from Heidelberg USA, Inc. (Kennesaw, Ga.).

After on-press developing, printing can then be carried out by successively applying a fountain solution and then lithographic ink to the image on the surface of the plate. The fountain solution is taken up and maintained by the unimaged regions, i.e., the surface of the hydrophilic substrate revealed by the imaging and on-press development process, and the ink is accepted by the imaged regions, i.e., the regions not removed by the development process. The ink is then transferred to a suitable receiving medium (such as cloth, paper, metal, glass or plastic) either directly or indirectly using an offset printing blanket to provide a desired impression of the image thereon.

The printing plate precursor according to the present invention can be transformed into a printing plate not only by on-press developing that is performed on a cylinder of a lithographic printing machine, but also by a developing process using a conventional auto-developing machine. As the developer to be used for the developing process using the conventional auto-developing machine can be an alkaline developer with a pH of 10 or more which is common in the art, as well as an acidic or weak-alkaline developer with a pH of less than 10. The developing process can be not only a general developing process composed of a developing step, a rinsing process and a gumming process but also another developing process wherein the developing step and the gumming step are consolidated into one step performed by using only one liquid.

Following development, a postbake can optionally be used to improve plate durability.

As explained above, it is possible for the lithographic printing plate precursor according to the present invention to image by scanning exposure based on digital signals, and to mount the imaged one directly on a press machine to perform printing.

The present invention provides at least the following embodiments and combinations thereof, but other combinations of features are considered to be within the present invention as a skilled artisan would appreciate from the teaching of this disclosure:

1. A lithographic printing plate precursor, comprising:

a substrate; and

an imaging layer formed on the substrate,

wherein

the imaging layer is prepared from a composition comprising

at least one radical-polymerizable compound,

at least one radical polymerization initiator, and

at least one polymer particle that has an average particle diameter of 300 nm or more, and comprises two or more types of poly(alkyleneoxide) moieties.

2. The lithographic printing plate precursor of embodiment 1, wherein the average particle diameter of the polymer particle ranges from 300 to 2000 nm.

3. The lithographic printing plate precursor of embodiment 1 or 2, wherein the polymer that has two or more types of poly(alkyleneoxide) moieties is a polymer having

a main chain which comprises no poly(alkyleneoxide) moiety, and

two or more pendant groups comprising the two or more poly(alkyleneoxide) moieties.

4. The lithographic printing plate precursor according to embodiment 3, wherein the pendant group is represented by any of the general formulae (1) through (4), and general formula (1) is:

—COO—[(CH₂)ₓ(CH(R¹))O]_{y}—R² (1)

general formula (2) is:

—COO—[(CH(R¹))(CH₂)ₓO]_{y}—R² (2)

wherein in general formulae (1) and (2),

x is an integer from 1 to 5,

y is an integer from 1 to 400,

R¹ independently denotes a hydrogen atom or a methyl group, and

R² denotes a hydrogen atom or a monovalent hydrocarbon group having 1 to 8 carbon atoms,

general formula (3) is:

—COO—[(CH₂)_{z}(CH(R³))O]ₘ—[(CH₂)ₙ(CH(R⁴)O]_{q}—R⁵ (3)

general formula (4) is:

—COO—[(CH(R³))(CH₂)_{z}O]ₘ—[(CH(R⁴))(CH₂)ₙO]_{q}—R⁵ (4)

wherein in general formulae (3) and (4),

each of n and z is independently an integer from 1 to 5,

each of m and q is independently an integer from 1 to 200,

R³ and R⁴ independently denotes a hydrogen atom or a methyl group, provided that R³ and R⁴ are different if n and z are the same number, and

R⁵ denotes a hydrogen atom or a monovalent hydrocarbon group having 1 to 8 carbon atoms.

5. The lithographic printing plate precursor of any of embodiments 1 to 4, wherein the polymer is at least derived from at least two selected from the group consisting of poly(alkyleneglycol)alkylether(meth)acrylates and poly(alkyleneglycol)(meth)acrylates.

6. The lithographic printing plate precursor of any of embodiments 1 to 5, wherein the polymer further has at least one group selected from the group consisting of a cyano group, an aryl group, and an amide group.

7. The lithographic printing plate precursor of embodiment 6, wherein the polymer is at least derived from

at least two selected from the group consisting of poly(alkyleneglycol)alkylether(meth)acrylates and poly(alkyleneglycol)(meth)acrylates, and

(meth)acrylonitrile, styrene, (meth)acrylamide or a combination thereof.

8. The lithographic printing plate precursor of any of embodiments 1 to 7, wherein the polymer particle is present in the imaging layer in an amount of from 1 to 60% by mass, based on the solid content of the imaging layer.

9. The lithographic printing plate precursor of any of embodiments 1 to 8, wherein the radical-polymerizable compound has at least one poly(alkyleneoxide) moiety.

10. The lithographic printing plate precursor of any of embodiments 1 to 9, wherein the radical-polymerizable compound is a multi-functional urethane acrylate.

11. The lithographic printing plate precursor of embodiment 10, wherein the multi-functional urethane acrylate has a molecular weight of 2000 or more.

12. The lithographic printing plate precursor of any of embodiments 1 to 11, wherein the radical polymerization initiator comprises a heat-polymerization initiator.

13. The lithographic printing plate precursor of embodiment 12, wherein the heat-polymerization initiator comprises an onium salt.

14. The lithographic printing plate precursor of embodiment 12 or 13, wherein the radical polymerization initiator comprises a photo-thermal conversion material.

15. The lithographic printing plate precursor of embodiment 14, wherein the photo-thermal conversion material is a cyanine dye.

16. The lithographic printing plate precursor of any of embodiments 1 to 15, wherein the imaging layer is the top layer.

17. The lithographic printing plate precursor of any of embodiments 1 to 15, wherein an oxygen bather layer is present on the imaging layer.

18. A process for preparing a lithographic printing plate, comprising a step of on-press developing the lithographic printing plate precursor of any of embodiments 1 to 17.

19. The process of embodiment 18, comprising the steps of:

image-wise exposing the lithographic printing plate precursor;

mounting the lithographic printing plate precursor on press; and

on-press developing the lithographic printing plate precursor by contacting it with either ink, a fountain solution, or both an ink and fountain solution.

20. The process of embodiment 18, comprising the steps of:

mounting the lithographic printing plate precursor on press;

image-wise exposing the lithographic printing plate precursor; and

on-press developing the lithographic printing plate precursor by contacting it with either ink, a fountain solution, or both an ink or fountain solution.

### EXAMPLES

The present invention will be described in more detail by way of examples, which however should not be construed as limiting the scope of the present invention. The “%” hereafter means % by mass (weight).

Hereinafter, “average particle diameter” was measured with a measurement apparatus using a dynamic light scattering method. Specifically, the average particle diameter was measured with a Zetasizer Nano series Nano-S-90 by Malvern (Worcestershire, United Kingdom) under the conditions that the measurement type was “size”, a glass cell was used, the measurement angle was 90°, and the measurement scanning rate was 50 times for about 30 seconds for each sample. As the measurement sample, a dispersion of polymer particles in a concentration of 0.06 g/L in a mixture of solvents of 1-propanol and water in a mixing ratio of 75% by mass/24% by mass.

### Synthesis Example 1

950.6 g of deionized water was charged into a 10 liter size glass flask reactor which has a thermometer, a condenser, a stirrer and an N2 gas inlet. 146.22 g of PEGMA*¹) (50% by mass solution), 54.02 g of polypropylene glycol mono methacrylate*²) and 3,032.6 g of 1-propanol were added into the reactor, and heated up to 76° C. while stirring under an N2 gas flow. 254.26 g of styrene and 889.78 g of acrylonitrile were charged into another vessel, and 12.0 g of 2,2′-azobis(2-methylbutyronitrile) (Vazo 67 marketed by DuPont) was added thereto to form a monomer pre-mix solution. The monomer pre-mix solution was transferred into the reactor with a constant rate pump for 2 hours, while maintaining the temperature at 76° C. After the monomer pre-mix solution transfer was completed, the reaction system in the reactor was stirred at 76° C. for 5 hours. Next, 8.54 g of 2,2′-azobis(2-methylbutyronitrile) (Vazo 67 marketed by DuPont) was added to the reactor, and the reaction system in the reactor was stirred at 76° C. for 3 hours. Then, 5.96 g of 2,2′-azobis(2-methylbutyronitrile) (Vazo 67 marketed by DuPont) was added to the reactor, and the reaction system in the reactor was stirred at 76° C. for 3 hours. Finally, 5.96 g of 2,2′-azobis(2-methylbutyronitrile) (Vazo 67 marketed by DuPont) was added to the reactor, and the reaction system in the reactor was stirred at 76° C. for 4 hours. Thus, 5400 g of Polymer Particle 1 was obtained. The average particle diameter of Polymer Particle 1 was 370 nm.

*1) PEGMA: Polyethyleneglycol methylether methacrylate (Sigma Aldrich Japan)
*2) Polypropyleneglycol mono methacrylate: Blemmer PP-800 (NOF Corporation)

### Synthesis Examples 2 to 10

Polymer Particles 2 to 10 were obtained in the same manner as in Synthesis Example 1, except that the time for transferring the monomer pre-mix solution was changed as shown in Table 1. The average particle diameter of each of Polymer Particles 2 to 10 is shown in Table 1.

TABLE 1

| | Monomer Premix | Average |
|---|---|---|
| Polymer | Transfer Time | Particle Diameter |
| Particle | (hours) | (nm) |
| 2 | 2.5 | 340 |
| 3 | 1.8 | 430 |
| 4 | 1.5 | 550 |
| 5 | 1.0 | 920 |
| 6 | 0.8 | 1200 |
| 7 | 3.0 | 295 |
| 8 | 4.5 | 240 |
| 9 | 6.0 | 200 |
| 10 | 8.0 | 180 |

### Synthesis Example 11

950.6 g of deionized water was charged into a 10 liter size glass flask reactor which has a thermometer, a condenser, a stirrer and an N2 gas inlet. 146.22 g of PEGMA (50% by mass solution), 54.02 g of polypropylene glycol mono methacrylate and 3,032.6 g of 1-propanol were added into the reactor, and heated up to 76° C. while stirring under an N2 gas flow. 190.67 g of styrene, 190.67 g of methacrylamide and 762.70 g of acrylonitrile were charged into another vessel, and 12.0 g of 2,2′-azobis(2-methylbutyronitrile) (Vazo 67 marketed by DuPont) was added thereto to form a monomer pre-mix solution. The monomer pre-mix solution was transferred into the reactor with a constant rate pump for 1.5 hours, while maintaining the temperature at 76° C. After the monomer pre-mix solution transfer was completed, the reaction system in the reactor was stirred at 76° C. for 5 hours. Next, 8.54 g of 2,2′-azobis(2-methylbutyronitrile) (Vazo 67 marketed by DuPont) was added to the reactor, and the reaction system in the reactor was stirred at 76° C. for 3 hours. Then, 5.96 g of 2,2′-azobis(2-methylbutyronitrile) (Vazo 67 marketed by DuPont) was added to the reactor, and the reaction system in the reactor was stirred at 76° C. for 3 hours. Finally, 5.96 g of 2,2′-azobis(2-methylbutyronitrile) (Vazo 67 marketed by DuPont) was added to the reactor, and the reaction system in the reactor was stirred at 76° C. for 4 hours. Thus, 5400 g of Polymer Particle 11 was obtained. The average particle diameter of Polymer Particle 11 was 660 nm.

### Synthesis Examples 12 and 13

Polymer Particles 12 and 13 were obtained in the same manner as in Synthesis Example 11, except that the time for transferring the monomer pre-mix solution was changed as shown in Table 2. The average particle diameter of each of Polymer Particles 12 and 13 are shown in Table 2.

TABLE 2

| | Monomer Premix | Average |
|---|---|---|
| Polymer | Transfer Time | Particle Diameter |
| Particle | (hours) | (nm) |
| 12 | 2.5 | 370 |
| 13 | 6.0 | 220 |

### Synthesis Example 14

950.6 g of deionized water was charged into a 10 liter size glass flask reactor which has a thermometer, a condenser, a stirrer and an N₂ gas inlet. 14622 g of PEGMA (50% by mass solution), 54.02 g of (polypropyleneglycol/polytetramethyleneglycol) methacrylate^{*3}) and 3,032.6 g of 1-propanol were added into the reactor, and heated up to 76° C. while stirring under an N₂ gas flow. 254.26 g of styrene and 889.78 g of acrylonitrile were charged into another vessel, and 12.0 g of 2,2′-azobis(2-methylbutyronitrile) (Vazo 67 marketed by DuPont) was added thereto to form a monomer pre-mix solution. The monomer pre-mix solution was transferred into the reactor with a constant rate pump for 1.5 hours, while maintaining the temperature at 76° C. After the monomer pre-mix solution transfer was completed, the reaction system in the reactor was stirred at 76° C. for 5 hours. Next, 8.54 g of 2,2′-azobis(2-methylbutyronitrile) (Vazo 67 marketed by DuPont) was added to the reactor, and the reaction system in the reactor was stirred at 76° C. for 3 hours. Then, 5.96 g of 2,2′-azobis(2-methylbutyronitrile) (Vazo 67 marketed by DuPont) was added to the reactor, and the reaction system in the reactor was stirred at 76° C. for 3 hours. Finally, 5.96 g of 2,2′-azobis(2-methylbutyronitrile) (Vazo 67 marketed by DuPont) was added to the reactor, and the reaction system in the reactor was stirred at 76° C. for 4 hours. Thus, 5400 g of Polymer Particle 14 was obtained. The average particle diameter of Polymer Particle 14 was 590 nm.

*3) (Polyethyleneglycol/polytetramethyleneglycol) methacrylate: Blemmer 55PET-800 (NOF Corporation)

### Synthesis Examples 15 and 16

Polymer Particles 15 and 16 were obtained in the same manner as in Synthesis Example 14, except that the time for transferring the monomer pre-mix solution was changed as shown in Table 3. The average particle diameter of each of Polymer Particles 15 and 16 are shown in Table 3.

TABLE 3

| | Monomer Premix | Average |
|---|---|---|
| Polymer | Transfer Time | Particle Diameter |
| Particle | (hours) | (nm) |
| 15 | 2.5 | 360 |
| 16 | 6.0 | 200 |

### Synthesis Example 17

950.6 g of deionized water was charged into a 10 liter size glass flask reactor which has a thermometer, a condenser, a stirrer and an N₂ gas inlet. 254.26 g of PEGMA (50% by mass solution) and 3,032.6 g of 1-propanol were added into the reactor, and heated up to 76° C. while stirring under an N₂ gas flow. 190.67 g of styrene, 190.67 g of methacrylamide, and 762.70 g of acrylonitrile were charged into another vessel, and 12.0 g of 2,2′-azobis(2-methylbutyronitrile) (Vazo 67 marketed by DuPont) was added thereto to form a monomer pre-mix solution. The monomer pre-mix solution was transferred into the reactor with a constant rate pump for 2.0 hours, while maintaining the temperature at 76° C. After the monomer pre-mix solution transfer was completed, the reaction system in the reactor was stirred at 76° C. for 5 hours. Next, 8.54 g of 2,2′-azobis(2-methylbutyronitrile) (Vazo 67 marketed by DuPont) was added to the reactor, and the reaction system in the reactor was stirred at 76° C. for 3 hours. Then, 5.96 g of 2,2′-azobis(2-methylbutyronitrile) (Vazo 67 marketed by DuPont) was added to the reactor, and the reaction system in the reactor was stirred at 76° C. for 3 hours. Finally, 5.96 g of 2,2% azobis(2-methylbutyronitrile) (Vazo 67 marketed by DuPont) was added to the reactor, and the reaction system in the reactor was stirred at 76° C. for 4 hours. Thus, 5400 g of Polymer Particle 17 was obtained. The average particle diameter of Polymer Particle 17 was 260 nm.

### Synthesis Example 18

Polymer Particle 18 was obtained in the same manner as in Synthesis Example 17, except that the time for transferring the monomer pre-mix solution was changed to 4.5 hours. The average particle diameter of Polymer Particle 18 was 178 nm.

### Invention Example 1

### Substrate

The surface of an aluminum sheet was subjected to an electrolytic roughening treatment in a 2% hydrochloric acid bath to obtain a grained aluminum sheet with an average roughness (Ra) of 0.5 μm. Furthermore, the grained aluminum sheet was subjected to an anodizing treatment in an aqueous phosphoric acid solution to form an oxide film at amount of 2.5 g/m².

Next, a coating solution for an under layer shown in the following Table 4 was applied with a bar coater such that the amount of a dried coating was 0.03 g/m², was dried at 120° C. for 40 seconds, and cooled down to 20 to 27° C., to obtain a substrate with the under layer.

TABLE 4
Coating Solution for Under Layer

| Component | Amount | |
|---|---|---|
| Polyacrylic acid aqueous solution (40% by mass) | 3.0 | g |
| (Jurymer AC-10S marketed by TOAGOSEI | | |
| Water | 27.0 | g |

### Image Forming Layer

On the substrate with the under layer obtained above, a coating solution shown in the following Table 5 was coated using a bar coater, followed by drying at 110° C. for 40 seconds, and further cooling to 20 to 27° C. Thus, a lithographic printing plate precursor was obtained. The amount of the dried coating was 1.0 g/m².

TABLE 5
Coating Solution for Image Forming Layer

| Components | Amount | |
|---|---|---|
| Polymer Particle 1 of Synthesis Example 1 | 7.00 | g |
| (24% by mass solution) | | |
| Hydroxypropylcellulose | 0.25 | g |
| Urethane acrylate*⁴⁾ | 1.25 | g |
| Sartomer SR399*⁵⁾ | 0.75 | g |
| Irgacure ® 250*⁶⁾ | 0.25 | g |
| Infrared absorbing dye of the following | 0.15 | g |
| Chemical Formula 1 | | |
| 3-Mercapto-1,2,4-triazole*⁷⁾ | 0.05 | g |
| BYK ® 336*⁸⁾ | 0.16 | g |
| 1-Propanol | 38.92 | g |
| Methyl ethyl ketone | 41.90 | g |
| γ-Butyrolactone | 0.92 | g |
| Water | 8.40 | g |

*⁴⁾2-Butanone solution with a concentration of 80% by mass of a polymerizable compound obtained by reacting Desmodur ® N100 (aliphatic polyisocyanate resin including hexamethylene diacrylates marketed by Bayer) with hydroxyethylacrylate and pentaerythritoltriacrylate
*⁵⁾Trimethylolpropanetetraacrylate (marketed by Sartomer Company)
*⁶⁾Propylenecarbonate solution with a concentration of 75% by mass of iodonium (4-methoxyphenyl[4-(2-methylpropyl)phenyl]hexafluorophosphate (marketed by Chiba Specialty Chemicals)
*⁷⁾3-Mercapto-1,2,4-triazole available from PCAS (France)
*⁸⁾Xylene/methoxypropyl acetate solution with a concentration of 25% by mass of a modified dimethylpolysiloxane copolymer

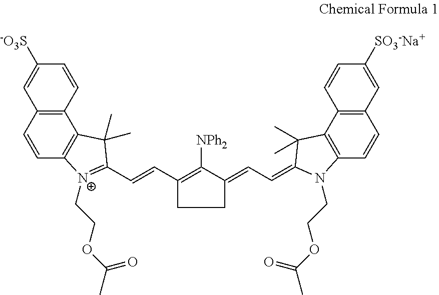

### Invention Examples 2 to 6

Lithographic printing plate precursors were obtained in the same manner as in Invention Example 1, except that Polymer Particles 2 to 6 obtained in Synthesis Examples 2 to 6 were used in place of Polymer Particle 1.

### Invention Examples 7 and 8

Lithographic printing plate precursors were obtained in the same manner as in Invention Example 1, except that Polymer Particles 11 and 12 obtained in Synthesis Examples 11 and 12 were used in place of Polymer Particle 1.

### Invention Examples 9 and 10

Lithographic printing plate precursors were obtained in the same manner as in Invention Example 1, except that Polymer Particles 14 and 15 obtained in Synthesis Examples 14 and 15 were used in place of Polymer Particle 1.

### Comparative Examples 1 to 4

Lithographic printing plate precursors were obtained in the same manner as in Invention Example 1, except that Polymer Particles 7 to 10 obtained in Synthesis Examples 7 to 10 were used in place of Polymer Particle 1.

### Comparative Example 5

A lithographic printing plate precursor was obtained in the same manner as in Invention Example 1, except that Polymer Particle 13 obtained in Synthesis Example 13 was used in place of Polymer Particle 1.

### Comparative Examples 6 to 8

Lithographic printing plate precursors were obtained in the same manner as in Invention Example 1, except that Polymer Particles 16 to 18 obtained in Synthesis Examples 16 to 18 were used in place of Polymer Particle 1.

### Evaluations:

### Exposure

Each of the lithographic printing plate precursors of Invention Examples 1-10 and Comparative Examples 1-8 was imagewise exposed at a rate of 150 mJ/cm², using Magnus 800 (Kodak) image setter with a laser which can emit an IR ray with a power of 23 W and a wavelength of 830 nm.

### On-Press Developability and Initial Ink Receptivity

Each of the exposed lithographic printing plate precursors was mounted on a printing press machine (MAN Roland R-201).

### On-Press Development Stability Over Time

Each of the lithographic printing plate precursors was stored (aged) 14 days at 40° C. under 80% relative humidity conditions. After storage, the aged lithographic printing plate precursors were exposed as above, and the thus-obtained plates were then mounted on a printing press machine (MAN Roland R-201) to evaluate the on-press developability after storage in the same manner as mentioned above.

### Printing Press Life

Each of the lithographic printing plate precursors was exposed as above, and the exposed one was mounted on a Komori S-26 press machine. A fountain solution (Presarto WS100 marketed by DIC Graphics)/isopropylalcohol/water=1/1/98 (volume ratio)) and printing ink (Fusion G Red N marketed by DIC Graphics) were supplied, and printing was performed at a printing rate of 6000 sheets/hour. When the number of printed paper sheets increased by continued printing, the imaging layer of the lithographic printing plate was gradually worn away, and the ink receptivity thereof deteriorated. Thus, the ink concentration on the printed paper sheets was reduced. The printing press life was evaluated by the number of printed paper sheets when the ink concentration (reflective concentration) thereon was reduced to 90% or less of that when the printing started.

The evaluation results of on-press developability, on-press development stability, initial ink receptivity and printing press life are shown in Table 6.

TABLE 6

| | | | | | | Printing |
|---|---|---|---|---|---|---|
| | | | | On-Press | | Press |
| | | Average | On-Press | Developability | Initial Ink | Life*¹¹⁾ |
| | Polymer | Particle | Developability*⁹⁾ | After Storage*⁹⁾ | Receptivity*¹⁰⁾ | (×10000 |
| Example | Particle | Size (nm) | (sheets) | (sheets) | (sheets) | sheets) |
| Invention 1 | 1 | 370 | 3 | 10 | 8 | 10 |
| Invention 2 | 2 | 340 | 3 | 10 | 8 | 10 |
| Invention 3 | 3 | 430 | 3 | 8 | 7 | 11 |
| Invention 4 | 4 | 550 | 3 | 7 | 6 | 11 |
| Invention 5 | 5 | 920 | 2 | 7 | 5 | 12 |
| Invention 6 | 6 | 1200 | 2 | 7 | 5 | 12 |
| Invention 7 | 11 | 660 | 2 | 8 | 8 | 11 |
| Invention 8 | 12 | 370 | 3 | 10 | 9 | 10 |
| Invention 9 | 14 | 590 | 2 | 8 | 7 | 10 |
| Invention 10 | 15 | 360 | 3 | 10 | 9 | 10 |
| Comparative 1 | 7 | 295 | 7 | 20 | 15 | 7 |
| Comparative 2 | 8 | 240 | 8 | 28 | 25 | 6 |
| Comparative 3 | 9 | 200 | 8 | 55 | 29 | 5.5 |
| Comparative 4 | 10 | 180 | 9 | 100 | 31 | 5 |
| Comparative 5 | 13 | 220 | 8 | 60 | 27 | 6 |
| Comparative 6 | 16 | 200 | 8 | 39 | 23 | 5.5 |
| Comparative 7 | 17 | 260 | 10 | 43 | 20 | 6 |
| Comparative 8 | 18 | 178 | 12 | 150 | 35 | 5 |

*⁹⁾On-press developability and on-press developability over time; the fewer, the better
*¹⁰⁾Initial ink receptivity; the fewer, the better
*¹¹⁾Printing press life; the more, the better

As is apparent from Table 6, the lithographic printing plate precursors of Invention Examples 1 to 10 exhibit better on-press developability, on-press development stability over time, ink receptivity and printing press life, as compared with the lithographic printing plate precursors of Comparative Examples 1 to 8.

1. A lithographic printing plate precursor, comprising:
a substrate; and
an imaging layer formed on the substrate,
wherein
the imaging layer is prepared from a composition comprising:
at least one radical-polymerizable compound,
at least one radical polymerization initiator, and
at least one polymer particle that has an average particle diameter of 300 nm or more, and comprises two or more types of poly(alkyleneoxide) moieties.

2. The lithographic printing plate precursor, according to claim 1, wherein the average particle diameter of the at least one polymer particle ranges from 300 to 2000 nm.

3. The lithographic printing plate precursor according to claim 1, wherein the at least one polymer particle is composed of a polymer that has two or more types of poly(alkyleneoxide) moieties is a polymer having a main chain which comprises no poly(alkyleneoxide) moiety, and two or more pendant groups comprising the two or more types of poly(alkyleneoxide) moieties.

4. The lithographic printing plate precursor according to claim 3, wherein the two or more pendant group are represented by any of the general formulae (1) through (4) and general formula (1) is:
—COO—[(CH₂)ₓ(CH(R¹))O]_{y}—R² (1)
general formula (2) is:
—COO—[(CH(R¹))(CH₂)ₓO]_{y}—R² (2)
wherein in general formulae (1) and (2),
x is an integer from 1 to 5,
y is an integer from 1 to 400,
R¹ independently denotes a hydrogen atom or a methyl group, and
R² denotes a hydrogen atom or a monovalent hydrocarbon group having 1 to 8 carbon atoms,
general formula (3) is:
—COO—[(CH₂)_{z}(CH(R³))O]ₘ—[(CH₂)ₙ(CH(R⁴)O]_{q}—R⁵ (3)
and general formula (4) is:
—COO—[(CH(R³))(CH₂)_{z}O]ₘ—[(CH(R⁴))(CH₂)ₙO]_{q}—R⁵ (4)
wherein in general formulae (3) and (4),
each of n and z is independently an integer from 1 to 5,
each of m and q is independently an integer from 1 to 200,
R³ and R⁴ independently denotes a hydrogen atom or a methyl group, provided that R³ and R⁴ are different if n and z are the same number, and
R⁵ denotes a hydrogen atom or a monovalent hydrocarbon group having 1 to 8 carbon atoms.

5. The lithographic printing plate precursor according to claim 1, wherein the at least one polymer particle is composed of a polymer that is at least derived from at least two selected from the group consisting of poly(alkyleneglycol)alkylether(meth)acrylates and poly(alkyleneglycol)(meth)acrylates.

6. The lithographic printing plate precursor according to claim 1, wherein the at least one polymer particle comprises a polymer that further comprises at least one group selected from the group consisting of a cyano group, an aryl group, and an amide group.

7. The lithographic printing plate precursor according to claim 6, wherein the at least one polymer particle comprises a polymer that is at least derived from
at least two selected from the group consisting of
poly(alkyleneglycol)alkylether(meth)acrylates and
poly(alkyleneglycol)(meth)acrylates, and (meth)acrylonitrile, styrene,
(meth)acrylamide or a combination thereof.

8. The lithographic printing plate precursor according to claim 1, wherein the at least one polymer particle is present in the imaging layer in an amount of from 1 to 60% by mass, based on the solid content of the imaging layer.

9. The lithographic printing plate precursor according to claim 1, wherein the radical-polymerizable compound has at least one poly(alkyleneoxide) moiety.

10. The lithographic printing plate precursor according to claim 1, wherein the radical-polymerizable compound is a multi-functional urethane acrylate.

11. The lithographic printing plate precursor according to claim 10, wherein the multi-functional urethane acrylate has a molecular weight of 2000 or more.

12. The lithographic printing plate precursor according to claim 1, wherein the radical polymerization initiator comprises a heat-polymerization initiator.

13. The lithographic printing plate precursor according to claim 12, wherein the heat-polymerization initiator comprises an onium salt.

14. The lithographic printing plate precursor according to claim 1, wherein the radical polymerization initiator comprises a photo-thermal conversion material.

15. The lithographic printing plate precursor according to claim 14, wherein the photo-thermal conversion material is a cyanine dye.

16. The lithographic printing plate precursor according to claim 1, wherein the imaging layer is the top layer.

17. The lithographic printing plate precursor according to claim 1, further comprising an oxygen barrier layer on the imaging layer.

18. A process for preparing a lithographic printing plate, comprising a step of on-press developing the lithographic printing plate precursor according to claim 1.

19. The process according to claim 18, comprising the steps of:
image-wise exposing the lithographic printing plate precursor;
mounting the lithographic printing plate precursor on press; and
on-press developing the lithographic printing plate precursor by contacting it with either ink, a fountain solution, or both an ink and fountain solution.

20. The process according to claim 18, comprising the steps of:
mounting the lithographic printing plate precursor on press;
image-wise exposing the lithographic printing plate precursor; and
on-press developing the lithographic printing plate precursor by contacting it with either ink, a fountain solution, or both an ink and fountain solution.
